(19) United States
(12) Patent Application Publication
(10) Pub. No.: US 2024/0234280 A1
(43) Pub. Date: Jul. 11, 2024

(54) SUBSTRATE WITH SUPPORT AND SEMICONDUCTOR DEVICE

(71) Applicant: TOPPAN HOLDINGS INC., Tokyo (JP)

(72) Inventors: Ryo WARIGAYA, Tokyo (JP); Ryoma TANABE, Tokyo (JP); Masahito TANABE, Tokyo (JP)

(73) Assignee: TOPPAN HOLDINGS INC., Tokyo (JP)

(21) Appl. No.: 18/611,641

(22) Filed: Mar. 20, 2024

Related U.S. Application Data
(63) Continuation of application No. PCT/JP2022/033435, filed on Sep. 6, 2022.

(30) Foreign Application Priority Data
Sep. 22, 2021 (JP) 2021-153732
Sep. 22, 2021 (JP) 2021-153750
Jul. 6, 2022 (JP) 2022-108781
Jul. 6, 2022 (JP) 2022-108783
Sep. 2, 2022 (JP) 2022-139742
Sep. 2, 2022 (JP) 2022-139745

(51) Int. Cl. H01L 23/498; H01L 21/48; H01L 23/00

(52) U.S. Cl. CPC H01L 23/49822; H01L 21/4857; H01L 23/49866; H01L 24/16; H01L 24/32; H01L 24/73; H01L 2224/16225; H01L 2224/32225; H01L 2224/73204

(57) ABSTRACT

A substrate including a support and a wiring board provided on the support, the wiring board includes an insulating film on the inside thereof configured by a first organic insulating resin; the wiring board has a first surface and a second surface each provided with electrodes that can be connected to a semiconductor element and the like; at least one of an upper surface layer and a lower surface layer of the wiring board is provided with an insulating film configured by a second organic insulating resin; and the second organic insulating resin has a CTE lower than that of the first organic insulating resin.

### CROSS-REFERENCE TO RELATED PATENT APPLICATIONS

This application is a continuation application filed under 35 U.S.C. § 111(a) claiming the benefit under 35 U.S.C. §§ 120 and 365(c) of International Patent Application No. PCT/JP2022/033435, filed on Sep. 6, 2022, which is based upon and claims the benefit to Japanese Patent Application Nos. 2021-153732, and 2021-153750, both filed on Sep. 22, 2021; Japanese Patent Application Nos. 2022-108781, and 2022-108783, both filed on Jul. 6, 2022; and Japanese Patent Application Nos. 2022-139742, and 2021-139745, both filed on Sep. 2, 2022, the disclosures of which are incorporated herein by reference in their entirety.

### TECHNICAL FIELD

The present invention relates to substrates with a support and semiconductor devices.

### BACKGROUND

When mounting semiconductor elements having fine wiring circuits on motherboards, the spacing between and size of electrodes serving as junction terminals of the semiconductor element do not necessarily match those of the motherboard. To address this, an intermediate substrate called a flip chip-ball grid array (FC-BGA) substrate is generally used between the semiconductor element and the motherboard. Such an intermediate substrate makes it possible to establish connection by converting the spacing between and size of the electrodes.

However, due to the increasing demand for faster and more highly integrated semiconductor devices, the FC-BGA substrates on which semiconductor elements are mounted are also required to have junction terminals with a narrower pitch and finer wiring.

On the other hand, for the spacing between the junction terminals between the FC-BGA substrate and the motherboard, they are required to have a pitch that is almost the same as the conventional pitch.

In order to cope with the narrowing of the pitch of the junction terminals of semiconductor elements and the accompanying miniaturization of the wiring in FC-BGA substrates, a multilayer wiring board having fine wiring is used between the FC-BGA substrate and the semiconductor element as an additional intermediate substrate also called an interposer.

Techniques for mounting a plurality of semiconductor elements on an FC-BGA substrate via such an interposer have emerged.

Early interposers were manufactured using a technique in the semiconductor element manufacturing process corresponding to a silicon wafer processing technique. However, when the semiconductor element manufacturing process is used, there is a problem that the manufacturing cost increases. In addition, regarding the interposers produced using silicon wafers, problems with their transmission characteristics due to the electrical characteristics of silicon itself have been pointed out.

There is also a method for forming a multilayer wiring board having a narrow pitch on the FC-BGA substrate by forming the interposer with a support such as a glass substrate and removing the substrate after mounting this on the FC-BGA substrate. This method is disclosed in PTL 1.

However, glass interposers have a problem in the processability of glass.

As a technique to compensate for the defects glass interposers have, there is a technique of forming an interposer using an organic insulating resin.

In the case where an interposer formed using an organic insulating resin is used, the wiring board is formed using an organic insulating resin and a wiring material on a support called a carrier. After mounting semiconductor elements on the wiring board and sealing it with resin, the support is removed, and the sealed wiring board is attached to the FC-BGA substrate to form a semiconductor device (PTL 2).

[Citation List] [Patent Literature] PTL 1: WO2018/047861; PTL 2: US 2021/0050298 A.

### SUMMARY OF THE INVENTION

### Technical Problem

However, when an interposer is formed using an organic insulating resin, thermal changes may cause the conduction layer of the wiring board to peel off or the organic insulating resin to crack because the organic insulating resin has a larger coefficient of thermal expansion (CTE) than the FC-BGA.

In the method in which a multilayer wiring board is formed on a support, such as a glass substrate, and this is mounted on an FC-BGA substrate, followed by separating the support, a semi-additive method is often used when forming a multilayer wiring layer on the support. However, insulating resin layers formed using such a semi-additive method contain no filler and tend to have a lower elastic modulus and a higher coefficient of thermal expansion (CTE), compared to filler-containing underfill layers and solder resist layers used in later processes.

In other words, if the surrounding temperature changes significantly after the interposer is attached to the FC-BGA, only the organic insulating resin in the wiring board deforms significantly, causing the wiring board to warp or generating stress inside the wiring board. Consequently, fine wiring layers or other layers may be peeled, or cracking may occur, originating from the areas of peeling or the areas where stress is concentrated.

The present invention has been made in light of the issues set forth above and aims to provide a wiring board or a substrate with a support, which relieves stress inside the wiring board and is less likely to cause cracking originating from areas where stress is concentrated, and to provide a semiconductor device.

### Solution to Problem

In order to solve the above issues, a substrate with a support according to the present invention is a substrate with a support, the substrate including a support and a wiring board provided on the support, wherein
the wiring board includes an insulating film on the inside thereof configured by a first organic insulating resin; and
an insulating film that is a surface layer of the wiring board is configured by a second organic insulating resin having a CTE lower than that of the first organic insulating resin.

In order to solve the above issues, a wiring board unit according to the present invention includes
a first wiring board, and a second wiring board joined with the first wiring board, in which, semiconductor elements are mounted on a surface facing away from a joining surface of the second wiring board joined with the first wiring board, wherein a reinforcement layer is provided as an outermost layer on one side of the second wiring board on which the semiconductor elements are mounted.

### Advantageous Effects of the Invention

According to the present invention, there can be provided a substrate with a support which relieves stress inside the wiring board and is less likely to cause cracking originating from areas where stress is concentrated, and to provide a semiconductor device.

Furthermore, in a method in which a fine wiring layer (corresponding to the second wiring board) is formed on a support substrate, the wiring layer on the support substrate is mounted, for example, on an FC-BGA wiring board (corresponding to the first wiring board), and semiconductor chips are mounted on the second wiring board, stress inside the second wiring board can be relieved, cracking originating from areas where stress is concentrated can be prevented, and reliability of the wiring board unit can be improved.

Problems, configurations, and advantageous effects other than those described above will be clarified in the following description on modes for carrying out the invention.

### BRIEF DESCRIPTION OF THE DRAWINGS

FIG. 1A is a schematic diagram illustrating a semiconductor element and the like.

FIG. 1B is a schematic diagram illustrating a substrate with a support.

FIG. 1C is a schematic diagram illustrating a wiring board, a substrate with a support, and a semiconductor device.

FIG. 1D is a schematic diagram illustrating a wiring board, a substrate with a support, and a semiconductor device.

FIG. 2A is a diagram illustrating a mode of a wiring board from which a support has been peeled off.

FIG. 2B is a diagram illustrating a mode of a wiring board from which a support has been peeled off.

FIG. 2C is a diagram schematically illustrating another wiring board on which the wiring board from which the support has been peeled is placed.

FIG. 2D is a diagram illustrating a mode of a substrate with a support being connected to other wiring board.

FIG. 3A is a cross-sectional view illustrating a substrate with a support according to a first embodiment.

FIG. 3B is a cross-sectional view illustrating a substrate with a support according to the first embodiment.

FIG. 3C is a cross-sectional view illustrating a substrate with a support according to a second embodiment.

FIG. 3D is a cross-sectional view illustrating a substrate with a support according to the second embodiment.

FIG. 4A is a cross-sectional view illustrating a substrate with a support according to a third embodiment.

FIG. 4B is a cross-sectional view illustrating a substrate with a support according to a fourth embodiment.

FIG. 4C is a cross-sectional view illustrating a substrate with a support according to the fourth embodiment.

FIG. 5 is a diagram illustrating a production method according to the first embodiment.

FIG. 6 is a diagram illustrating the production method according to the first embodiment.

FIG. 7 is a diagram illustrating the production method according to the first embodiment.

FIG. 8 is a diagram illustrating the production method according to the first embodiment.

FIG. 9 is a cross-sectional view illustrating the case where electrodes are formed on a substrate with a support.

FIG. 10A is a cross-sectional view illustrating a production method in which copper posts are formed on a substrate with a support.

FIG. 10B is a cross-sectional view illustrating the production method in which copper posts are formed on a substrate with a support.

FIG. 10C is a cross-sectional view illustrating the production method in which copper posts are formed on a substrate with a support.

FIG. 10D is a cross-sectional view illustrating the production method in which copper posts are formed on a substrate with a support.

FIG. 11A is a cross-sectional view illustrating a production method in which copper posts are formed on a substrate with a support.

FIG. 11B is a cross-sectional view illustrating the production method in which copper posts are formed on a substrate with a support.

FIG. 11C is a cross-sectional view illustrating the production method in which copper posts are formed on a substrate with a support.

FIG. 11D is a cross-sectional view illustrating the production method in which copper posts are formed on a substrate with a support.

FIG. 12 is a cross-sectional view illustrating the case in which a semiconductor device and others are mounted to a substrate with a support in which a second insulating resin does not cover part of a first surface of the substrate with a support.

FIG. 13A is a cross-sectional view illustrating a state in which a reinforcement layer is formed.

FIG. 13B is a cross-sectional view illustrating a state in which the reinforcement layer is patterned.

FIG. 13C is a cross-sectional view illustrating a state in which the reinforcement layer is patterned.

FIG. 14 is a cross-sectional view illustrating a state in which a release layer is formed on a support.

FIG. 15A is a cross-sectional view illustrating a state in which a photosensitive resin layer is formed.

FIG. 15B is a cross-sectional view illustrating a state in which the photosensitive resin layer is patterned.

FIG. 15C is a cross-sectional view illustrating a state in which a seed adhesion layer is formed.

FIG. 15D is a cross-sectional view illustrating a state in which a seed layer is formed.

FIG. 15E is a cross-sectional view illustrating a state in which a conductor layer is formed.

FIG. 15F is a cross-sectional view illustrating a state in which the conductor layer and the seed layer are polished using surface polishing.

FIG. 15G is a cross-sectional view illustrating a state in which the seed adhesion layer and the photosensitive resin layer are polished using surface polishing to form electrodes for establishing a connection with semiconductor elements.

FIG. 15H is a cross-sectional view illustrating a second mode of forming connection holes in a fine wiring layer.

FIG. 15I is a cross-sectional view illustrating the second mode of forming connection holes in a fine wiring layer.

FIG. 15J is a cross-sectional view illustrating a third mode of forming connection holes in a fine wiring layer.

FIG. 15K is a cross-sectional view illustrating the third mode of forming connection holes in a fine wiring layer.

FIG. 16A is a cross-sectional view illustrating a state in which a photosensitive resin layer for vias is formed.

FIG. 16B is a cross-sectional view illustrating a state in which a photosensitive resin layer for vias and a wiring section is formed.

FIG. 16C is a cross-sectional view illustrating a state in which a seed adhesion layer is formed.

FIG. 16D is a cross-sectional view illustrating a state in which a seed layer is formed.

FIG. 16E is a cross-sectional view illustrating a state in which a conductor layer is formed.

FIG. 16F is a cross-sectional view illustrating a state in which vias and a wiring section are formed using surface polishing.

FIG. 17A is a cross-sectional view illustrating a state in which multilayer wiring is formed repeating the processes shown in FIGS. 16A to 16F.

FIG. 17B is a cross-sectional view illustrating a state in which multilayer wiring is formed using a SAP method.

FIG. 18A is a cross-sectional view illustrating a state in which a photosensitive resin layer is formed.

FIG. 18B is a cross-sectional view illustrating a state in which a seed adhesion layer is formed.

FIG. 18C is a cross-sectional view illustrating a state in which a seed layer is formed.

FIG. 18D is a cross-sectional view illustrating a state in which a resist pattern is formed.

FIG. 18E is a cross-sectional view illustrating a state in which a conductor layer is formed.

FIG. 18F is a cross-sectional view illustrating a state in which the resist pattern is removed.

FIG. 18G is a cross-sectional view illustrating a state in which unnecessary seed adhesion layer portions and seed layer portions are etched away.

FIG. 19A is a cross-sectional view illustrating a state in which a solder resist layer is formed.

FIG. 19B is a cross-sectional view illustrating a state in which a surface treatment layer and solder joints are formed to complete a substrate with a support.

FIG. 20A is a cross-sectional view illustrating a state in which a substrate with a support is joined with an FC-BGA substrate and sealed with an underfill layer.

FIG. 20B is a cross-sectional view illustrating a state in which laser light is applied to the release layer.

FIG. 20C is a cross-sectional view illustrating a state in which the support is removed.

FIG. 20D is a cross-sectional view illustrating a state in which semiconductor elements are mounted.

FIG. 21A is an enlarged detailed cross-sectional view of the border A-A′ of the present embodiment (damascene method).

FIG. 21B is an enlarged detailed cross-sectional view of the border A-A′ of the present embodiment (SAP method).

FIG. 21C is an enlarged detailed cross-sectional view illustrating a comparative example.

FIG. 22 is a cross-sectional view illustrating a state in which an intermediate layer is formed between a release layer and a reinforcement layer, according to a second embodiment.

FIG. 23 is a cross-sectional view illustrating a state in which the reinforcement layer is patterned, according to the second embodiment.

FIG. 24 is a cross-sectional view illustrating a state in which a surface treatment layer and solder joints are formed to complete a substrate with a support, according to the second embodiment.

### DESCRIPTION OF THE EMBODIMENTS

With reference to the drawings, some embodiments of the present invention will be described. In the following description of the drawings, components identical with or similar to each other are given the same or similar reference signs. It should be noted that the drawings are only schematically illustrated, and thus the relationship between thickness and planar dimensions of the components, the thickness ratio between the layers, and the like are not to scale. Accordingly, specific thicknesses or dimensions should be understood referring to the following description. As a matter of course, dimensional relationships or ratios may be different between the drawings.

The embodiments described below only exemplify devices or methods embodying the technical idea of the present invention. The technical idea of the present invention should not limit the materials, shapes, structures, layouts, and the like of the components to those described below. The technical idea of the present invention can be modified in various ways within the technical scope defined in the claims.

In the present disclosure, the term “surface” may refer to not only the surface of a plate-like member but also, for a layer included in the plate-like member, an interface with the layer that is substantially parallel to the surface of the plate-like member. The term “upper surface” or “lower surface” refers to a surface shown in the upward or downward direction in a drawing when a plate-like member or a layer included in the plate-like member is shown in the drawing. The term “upper surface” or “lower surface” may also be referred to as “first surface” or “second surface”.

The term “side surface” refers to a surface or a thick part of a plate-like member or of a layer included in the plate-like member. Furthermore, part of a surface and a side surface may be collectively referred to as “edge portion”.

The term “above” refers to the vertically upward direction when a plate-like member or a layer is horizontally placed. The term “above” and the term “below” that is opposite to the “above” may be referred to as “Z-axis direction”, and the horizontal direction may be referred to as “X-axis direction” or “Y-axis direction”.

The term “planar shape” or “in plan view” refers to a shape when a surface or a layer is seen from above. The term “cross-sectional shape” or “as viewed in cross section” refers to a shape as seen in a horizontal direction when a plate-like member or a layer is sectioned in a specific direction.

The term “semiconductor element and the like” refers to elements including semiconductor elements, electronic parts with substantially the same size as the semiconductor elements, and wiring boards.

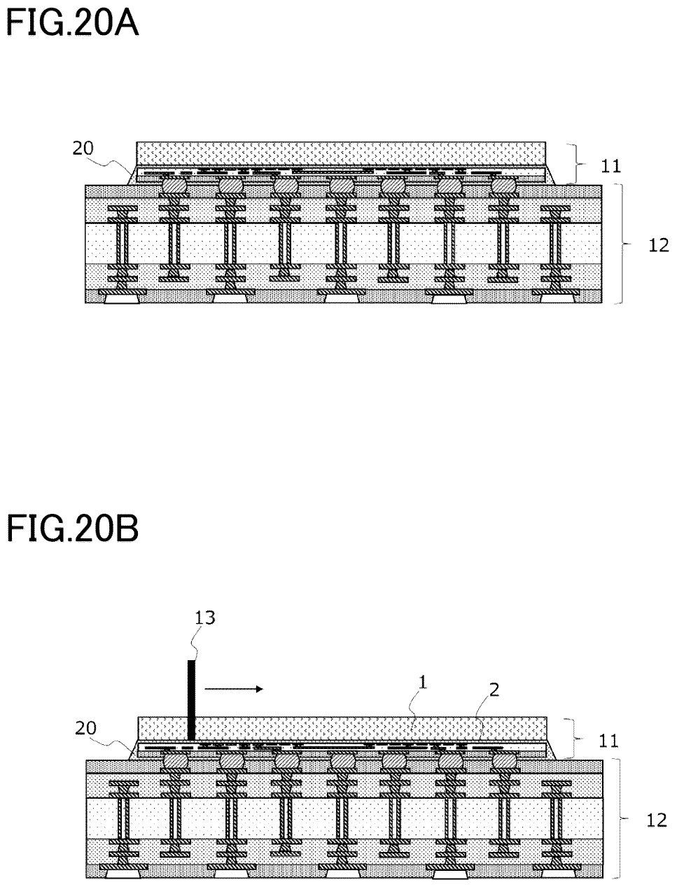

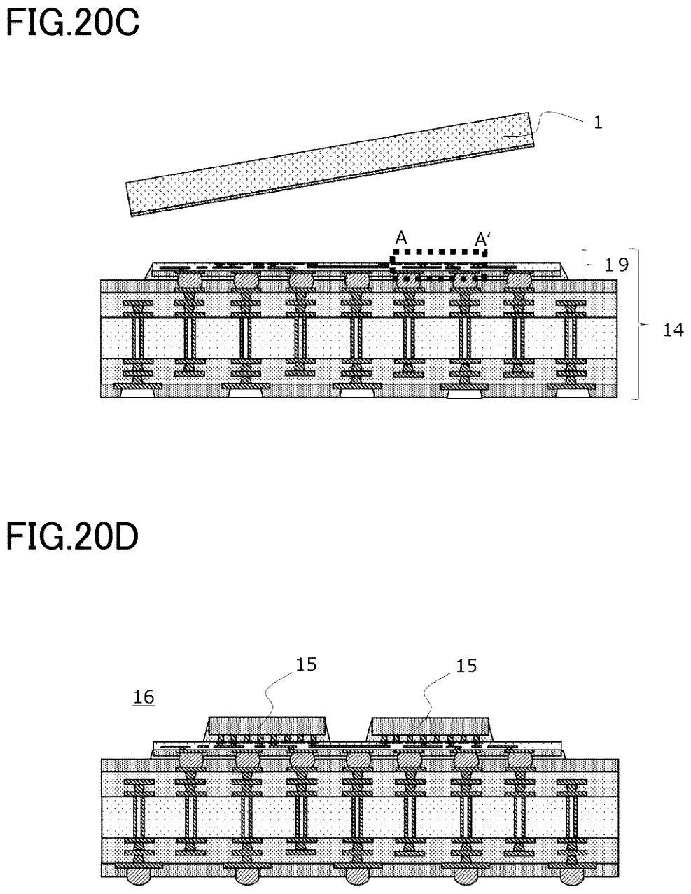

The release layer may be, for example, a resin which becomes peelable due to heat generation as a result of absorbing light such as UV light or due to alteration, or a resin which becomes peelable due to foaming as a result of being heated. If a resin is used that becomes peelable due to light such as UV light, e.g., laser light, the support 1 can be removed from the joined body of the substrate 11 with a support and the FC-BGA substrate 12 by applying light, as shown in FIG. 20B, to the support 1 from the surface thereof facing away from the surface provided with the release layer.

The release layer can be selected, for example, from organic resins such as epoxy resins, polyimide resins, polyurethane resins, silicone resins, polyester resins, oxetane resins, maleimide resins, and acrylic resins, or from inorganic layers such as an amorphous silicon layer, a gallium nitride layer, and metal oxide layers. The material of the release layer 2 may contain additives such as photolysis accelerants, light absorbers, sensitizers, and fillers.

The release layer may be formed of a plurality of layers. For example, a protective layer may be further provided on the release layer for the purpose of protecting the fine wiring layer formed of multiple layers (second wiring board) formed on the support, or a layer enhancing adhesion to the support may be provided as an underlayer of the release layer. Furthermore, a laser light reflective layer or a metal layer may be provided between the release layer and the fine wiring layer formed of multiple layers which is formed on the release layer, and thus the structure should not be limited by the present embodiment.

The support is preferred to have transparency, e.g., may be made of glass, because the release layer may be irradiated with light via the support. Glass has good flatness and high rigidity, and thus is suitable for forming a fine pattern for substrates with a support. In addition, glass has a low coefficient of thermal expansion (CTE) and is resistant to strain, and thus is excellent in securing pattern placement accuracy and flatness.

If glass is used as a support, the thickness of the glass is preferred to be large, e.g., 0.7 mm or more, and more preferred to be 1.1 mm or more, from the perspective of suppressing occurrence of warpage in the production process. Furthermore, the CTE of the glass is preferred to be 3 ppm/K or more and 15 ppm/K or less, and is more preferred to be around 9 ppm/K from the perspective of the CTEs of the FC-BGA substrate 12 and the semiconductor elements 15. Examples of the glass include quartz glass, borosilicate glass, non-alkali glass, soda glass, and sapphire glass.

However, if the support is not required to have light transmission properties when releasing the support, such as the case where a resin that foams due to heat is used as the release layer, the support can be made of metal or ceramics, for example, inducing less strain.

In the embodiments of the present disclosure provided below, a resin that becomes peelable due to absorption of UV light is used as the release layer, and glass is used as the support.

### First Embodiment

### Wiring Board, Substrate with Support, and Semiconductor Device

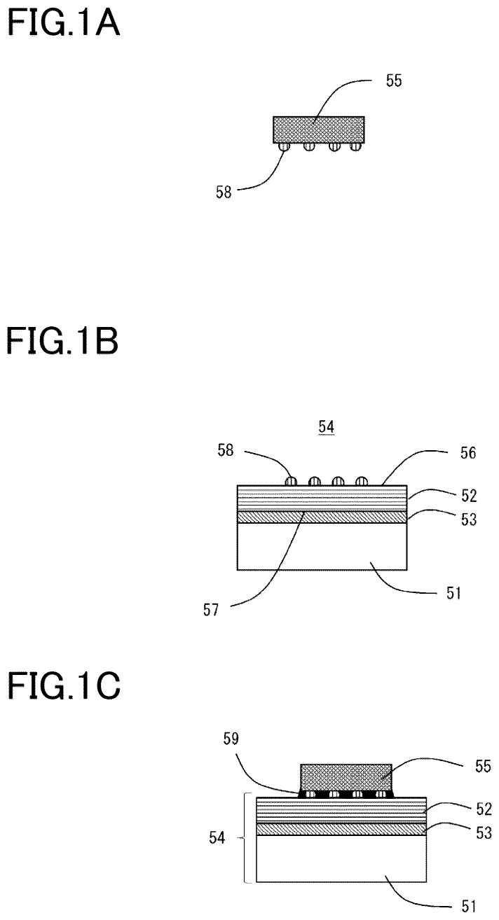

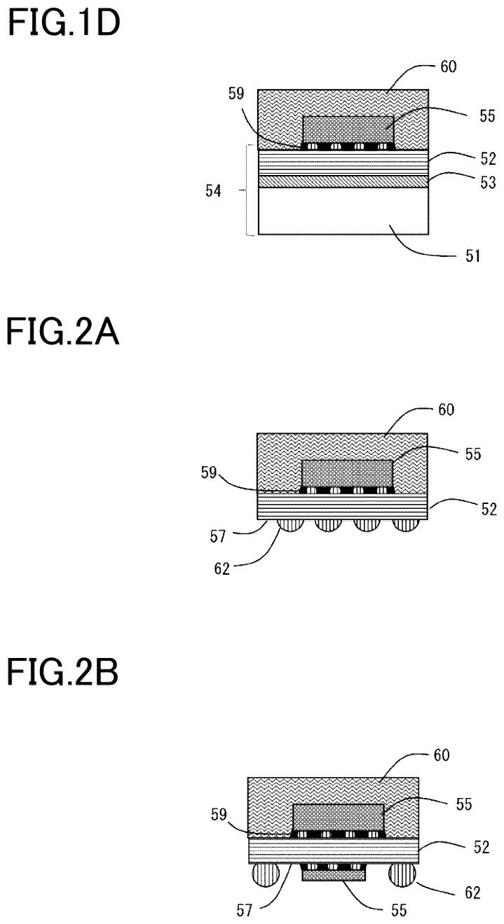

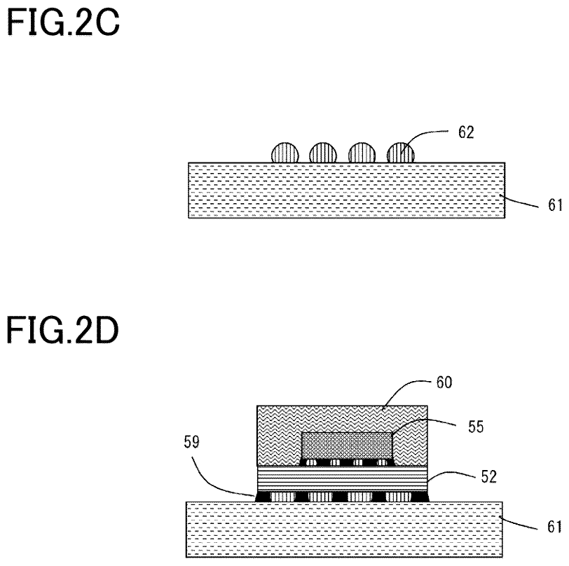

Referring to FIGS. 1A to 2D, first, an overview of a wiring board, a substrate with a support, a semiconductor device, and production processes will be described.

FIG. 1A is a schematic cross-sectional view illustrating a semiconductor element and the like 55 which are connected onto a substrate 54 with a support shown in FIG. 1B. FIG. 1B is a schematic cross-sectional view illustrating the substrate 54 with a support in which a wiring board 52 is formed on a support 51 via a release layer 53.

The support 51 is mainly formed of glass, and the wiring board 52 is configured using an organic insulating resin. The wiring board 52, semiconductor element and the like 55, and other wiring board 61 are illustrated in FIGS. 1A to 2D with the internal structures omitted.

The substrate 54 with a support shown in FIG. 1B, in which the wiring board 52 is formed on the support 51, may be referred to as a redistribution layer (RDL) with a carrier. An upper surface 56 of the wiring board 52 is referred to as a first surface, and a lower surface 57 thereof is referred to as a second surface.

The upper surface 56 of the wiring board 52 is provided with solder 58 for establishing an electrical connection with the semiconductor element and the like 55. The semiconductor element and the like 55 shown in FIG. 1A are also provided with solder 58 on the surface thereof to be connected to the substrate 54 with a support.

FIG. 1C is a schematic cross-sectional view illustrating a state in which the semiconductor element and the like 55 are mounted on the first surface, i.e., the upper surface 56, of the wiring board 52 of the substrate with a support shown in FIG. 1B, and fixed with an underfill 59.

FIG. 1D is a schematic cross-sectional view illustrating a state in which the substrate 54 with a support on which the semiconductor element and the like 55 are mounted as shown in FIG. 1C is further fixed with a molding resin 60.

Referring to FIGS. 2A to 2D, a description will be given of the processes of connecting the substrate with a support, to which the semiconductor element and the like 55 are fixed with the molding resin 60 shown in FIG. 1D, to other wiring board 61. Examples of the other wiring board 61 may include FC-BGA substrates.

First, the substrate with a support to which the semiconductor element and the like 55 are fixed with the molding resin 60 as shown in FIG. 1D is irradiated with UV light from the side of the support 51 that is glass. Consequently, the release layer 53 that is a functional layer exhibits a peeling function to peel the support 51 from the wiring board 52.

Next, as shown in FIG. 2A, solder or copper posts 62 are formed on the lower surface 57 (second surface) of the wiring board 52 to establish an electrical connection with the other wiring board 61.

As shown in FIG. 2B, a semiconductor element and the like may be formed on the lower surface 57 of the wiring board 52, in addition to the solder or the copper posts 62.

FIG. 2C is a schematic cross-sectional view illustrating the other wiring board 61 to which the wiring board 52 is connected, with the support 51 peeled off. The other wiring board 61 is also provided with solder or copper posts 62 on the surface to which the wiring board 52 is connected.

Next, as shown in FIG. 2D, the component shown in FIGS. 2A or 2B, i.e., the semiconductor element and the like 55 and the wiring board 52 fixed to each other, is connected to the other wiring board 61, with the underfill 59 applied therebetween to provide a semiconductor device.

Although FIG. 2D shows only the mode in which the components shown in FIGS. 2A and 2C are connected to each other, the component as shown in FIG. 2B, i.e., the wiring board 52 with the semiconductor element and the like 55 provided on both surfaces thereof, can be connected to the other wiring board 61.

With the configuration and the production processes described above, semiconductor elements with progressively narrower pitches can be mounted on other wiring board such as an FC-BGA substrate.

The above example has described that semiconductor elements are mounted on the substrate 54 with a support, and this is then connected to the other wiring board 61 such as an FC-BGA substrate.

However, the substrate 54 with a support, with the support 51 peeled off, may be connected to the other wiring board 61 such as an FC-BGA substrate before mounting semiconductor elements thereon, and then a semiconductor element and the like may be mounted thereon.

### Example Using Damascene Method

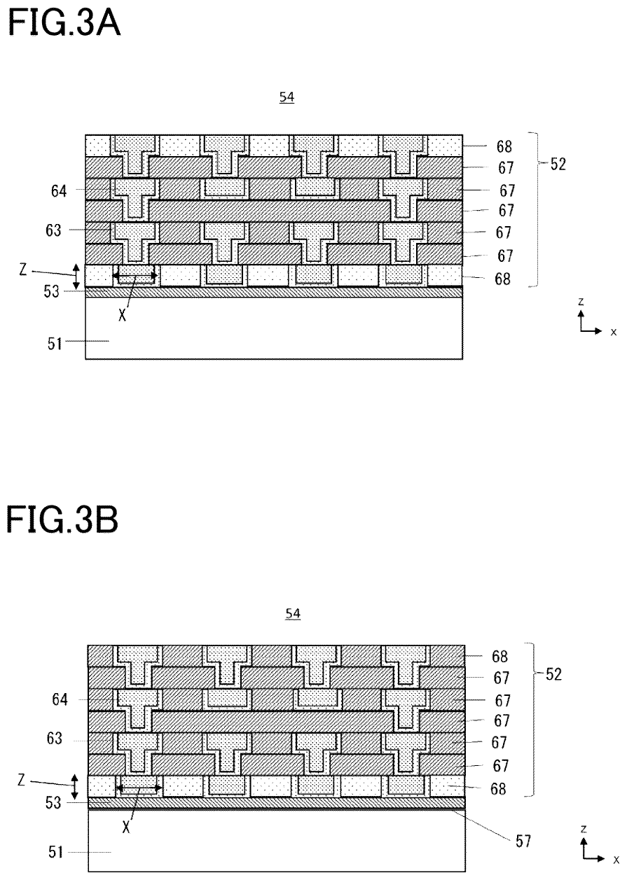

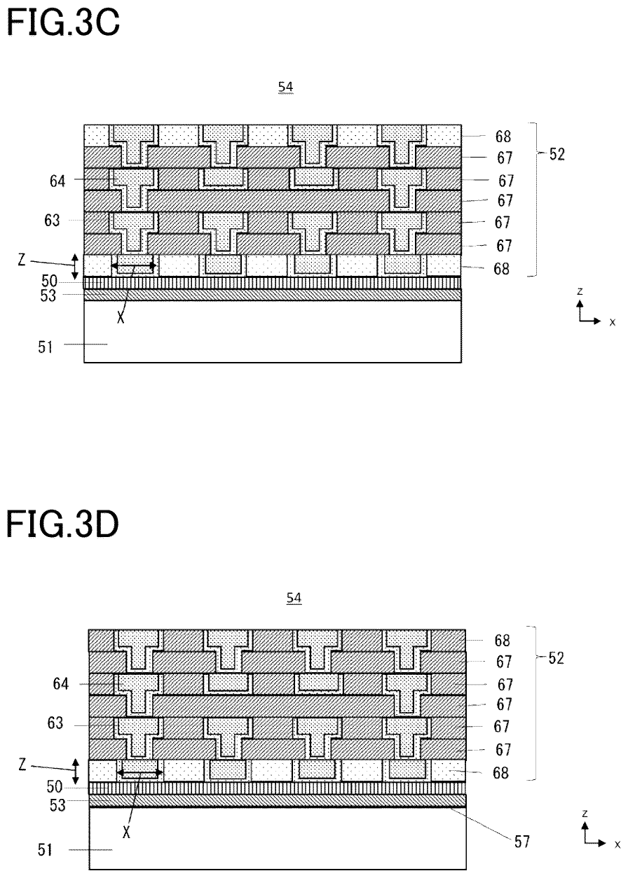

Next, referring to FIG. 3A, a substrate 54 with a support according to the first embodiment of the present disclosure will be described.

The substrate 54 with a support includes a wiring board 52 on a support 51 that is a glass substrate and is provided with a release layer 53 between the support 51 and the wiring board 52.

Inside the wiring board 52, wiring 64 is formed over multiple layers using a damascene method. The wiring 64 includes wiring portions and vias for connecting between the wiring portions in the Z direction, which are formed in the X-Y plane. (Formation of multilayer wiring using a damascene method will be described later.)

In the wiring board 52, reinforcement layers 68 as surface layer insulating films, and inner insulating films 67 are firmed.

The inner insulating films are formed of a first organic insulating resin, and the reinforcement layers are formed of a second organic insulating resin. The CTE of the second organic insulating resin is set to be lower than that of the first organic insulating resin. The CTE of the second organic insulating resin is preferred to be 40 ppm/K or lower. The second organic insulating film can contain fillers which can contain silicon or silicon compounds.

The wiring or the vias to connect wiring portions in the wiring board are made of copper or an alloy containing copper. Portions of the surfaces of these materials contacting the first or second organic insulating resin can be provided with respective portions of a barrier metal layer. The barrier metal layer can contain titanium or tantalum or compounds thereof.

In FIG. 3A, the reinforcement layers 68 of the wiring board 52 were both made of the second organic insulating resin. However, as shown in FIG. 3B, the uppermost reinforcement layer 68 in the Z direction may be made of the first organic insulating resin.

### Second Embodiment

Next, referring to FIGS. 3C and 3D, a description will be given of a second embodiment in which an intermediate layer 50 is provided between the release layer 53 and the reinforcement layer 68 in the first embodiment.

The second embodiment is different from the first embodiment in that the intermediate layer 50 is provided between the release layer 53 and the reinforcement layer 68. In the following description, identical reference signs are given to components that are the same as or equivalent to those in the first embodiment to simplify or omit repeated description.

In the second embodiment, the intermediate layer 50 is provided between the release layer 53 and the reinforcement layer 68 shown in each of FIGS. 3A and 3B. The intermediate layer 50 is formed using, for example, sputtering, vapor deposition, or the like. Examples of the materials that can be used include Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, Cu₃N₄, Cu alloys, or combinations of these. The intermediate layer 50 may be a single-layer or a multilayer.

In the second embodiment of the present disclosure, a titanium layer and then a copper layer are sequentially formed as the intermediate layer 50 by sputtering, from the perspective of electrical characteristics, ease of production, and cost. If the intermediate layer 50 is also used as an electrolytic plating power supply layer, the total thickness of the titanium layer and the copper layer is preferred to be 1 μm or less. In an embodiment of the present disclosure, Ti: 50 nm and Cu: 300 nm are formed.

Provision of such an intermediate layer 50 can improve adhesion between the release layer 53 and the reinforcement layer 68 and can prevent the support 51 from being easily peeled off.

Furthermore, the intermediate layer 50 plays a role of preventing mixing of the release layer 53 with the reinforcement layer 68 formed of a photosensitive insulating resin film, so that peeling can be reliably achieved between the release layer 53 and the intermediate layer 50.

### Effects of First and Second Embodiments

Insulating films forming a wiring board 52 based on the conventional art have been made of materials of substantially the same quality, and for generally used insulating films, photosensitive insulating resins have been used due to ease of patterning. Such photosensitive resins had CTEs in the range of around 50 to 80 ppm/K.

However, if a wiring board 52 is joined as part of the semiconductor device, the outer periphery thereof is covered, in many cases, with a filler-containing resin layer such as a solder resist or underfill. In this case, due to the difference in clastic modulus depending on the presence or absence of a filler, or due to the difference in deformation due to the difference in CTE, there has been a risk of causing warpage, peeling, or cracking in the wiring board 52 under temperature-changing conditions.

In order to match the physical property values, such as CTE, of the wiring board 52 with those of the material of the outer periphery, it may be considered that a filler-containing insulating resin may also be used for the photosensitive resin used for the wiring board 52. However, if a filler is contained in the insulating resin of the wiring board 52 in which fine wiring is to be formed, required miniaturization is not necessarily achieved because film thickness reduction or miniaturization is limited by the size of the filler. Also, if the production processes of such wiring boards include chemical-mechanical polishing (CMP), and if the filler-containing insulating films are polished in this process, part of the fillers may be polished and exposed and, if the fillers become detached, the wiring boards may be no longer flat and formation of fine wiring may become difficult. Therefore, filler-containing resins could not be necessarily used for all the insulating resins of the wiring board 52, in which fine wiring is to be formed.

In this regard, in the first and second embodiments of the present disclosure, difference in physical properties is changed stepwise in the wiring board 52 from the surface layers toward the inner layers, so that the physical property values can match between the wiring board 52 and the materials of the outer periphery. Specifically, for the surface layers, materials with physical property values close to those of the material of the outer periphery are selected and, for the inner layers of the wiring board 52, materials with usual physical property values are used, so that the physical property values, such as CTE, match between the wiring board 52 as a whole and the material of the outer periphery to thereby suppress occurrence of cracking.

In other words, the CTE of the second organic insulating resin that is the material of the reinforcement layers 68 of the wiring board 52 is made lower than that of the first organic insulating resin that is the material of the inner insulating films 67 of the wiring board 52. Thus, occurrence of cracking or delamination can be suppressed on the inside of the wiring board 52.

Various methods can be used as a method of lowering the CTE of insulating resins, among which, for example, incorporating fillers into insulating resins is relatively easy. If fillers are mixed in insulating resins, no significant problem may arise as long as the insulating resins mixed with fillers are located at portions such as in the reinforcement layers 68 where electrodes are mainly formed and fine wiring is not required to be formed.

### Third Embodiment

### Example Using SAP Method

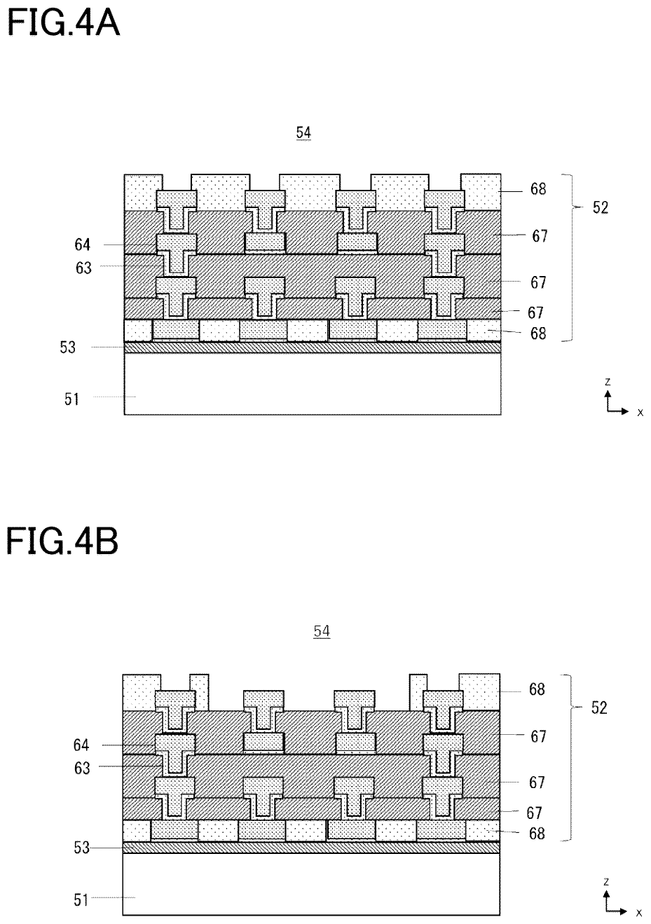

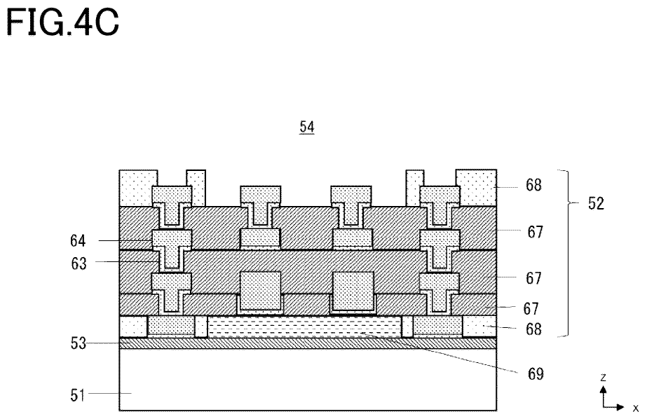

Next, referring to FIG. 4A, a substrate with a support according to a third embodiment of the present disclosure will be described.

The third embodiment is different from the first and second embodiments in that the wiring board 52 is produced using a known semi-additive method (SAP method). In the following description, identical reference signs are given to components that are the same as or equivalent to those in the first embodiment to simplify or omit repeated description.

In the third embodiment also, there is no significant difference in the effects, such as crack resistance, although the method of forming wiring is different from the damascene method. This will be described later when describing examples.

In FIG. 4A illustrating the third embodiment, the intermediate layer 50 disclosed in the second embodiment is not illustrated; however, similarly to the second embodiment, the intermediate layer 50 can also be provided in the third embodiment on the upper surface of the release layer 53.

### Fourth Embodiment

### Example in Which Second Insulating Resin Does not Cover Part of Wiring Board

Next, referring to FIG. 4B, a substrate with a support according to a fourth embodiment of the present disclosure will be described.

The fourth embodiment is different from the second and third embodiments in that the reinforcement layer 68 covers only part of the upper surface of the wiring board 52, and the first insulating resin of the inner insulating films 67 is exposed in the portions not covered. This can also be implemented in the first embodiment.

Also, as shown in FIG. 4C, part of the lower surface of the wiring board 52 may be provided with a plating resist 69, for example, in place of the reinforcement layer 68, and the plating resist 69 may be removed after peeling the support 51 to provide a structure in which only part of the lower surface of the wiring board 52 is covered by the reinforcement layer 68. The structure in which only part of the wiring board 52 is covered by the reinforcement layer 68 may be provided on one surface or both surfaces. This can also be implemented in the first embodiment.

### Effects

If filler-containing reinforcement layers 68 are used, and if the filler has a large particle size in particular, the filler may inhibit formation of fine wiring when performing resist patterning in a damascene method, for example. In a SAP method, the filler may inhibit filling of gaps between the insulating resins, for example, and sufficient covering cannot be necessarily achieved.

These may occur in particular in portions where the solder 58 is formed to serve as fine electrodes for mounting the semiconductor element and the like 55. Therefore, a method of not providing covering of the reinforcement layer 68 can be taken, centering on the regions where electrodes of the solder 58 are arranged to mount the semiconductor element and the like 55.

If some kind of patterning is performed in the regions where no filler-containing reinforcement layer 68 is used, the patterning may be performed in a photosensitive resin. In this case, there is an advantage that the patterning precision is improved compared to patterning in the filler-containing reinforcement layer 68.

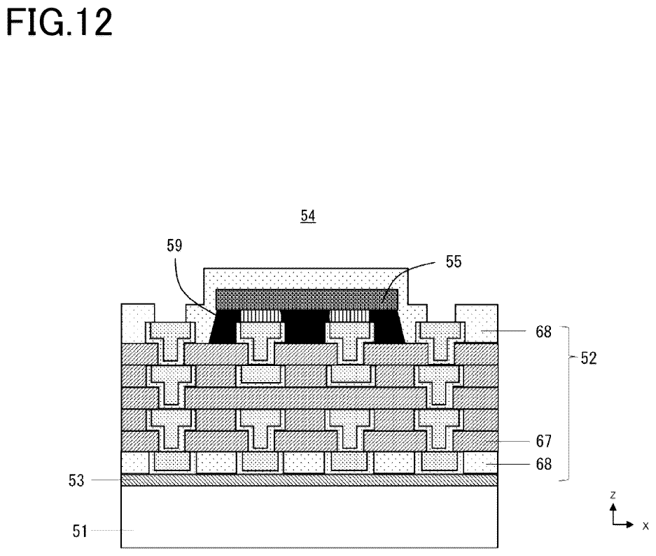

To cope with deterioration in strength due to not using a filler-containing reinforcement layer 68, the semiconductor element and the like 55 may be mounted in a later process, following which, portions not covered by the reinforcement layer 68 may be filled with the underfill 59 for fixture of these elements as shown in FIG. 12, to suppress occurrence of cracking or the like.

### Production Method for First Embodiment

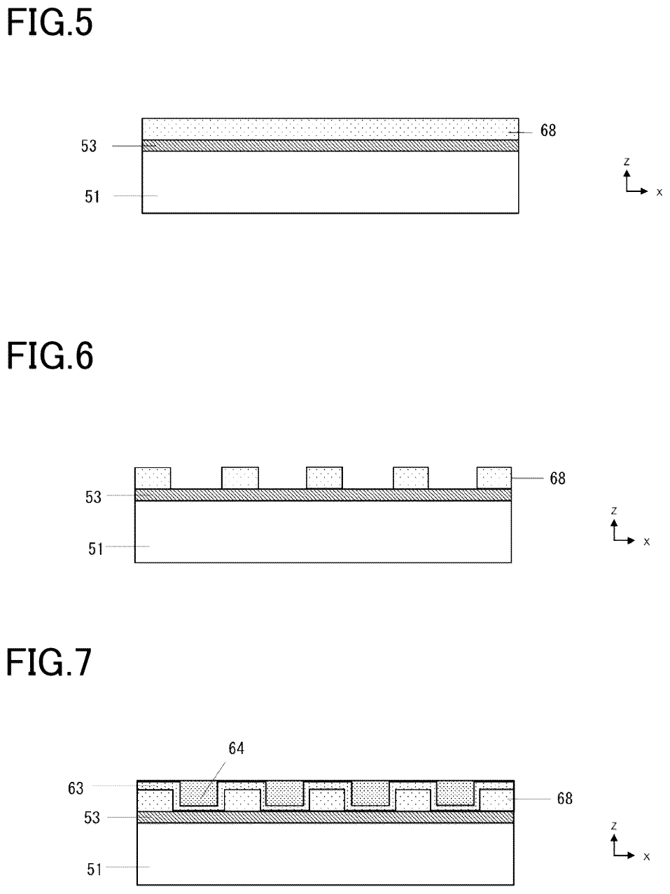

Next, referring to FIGS. 5 to 8, a production method for the first embodiment using a damascene method will be described.

As shown in FIG. 5, a release layer 53 is formed on a support 51 formed of a glass substrate.

Next, in the production method of the first embodiment, a filler-containing second organic insulating resin is applied onto the release layer 53 to provide a reinforcement layer serving as the reinforcement layer 68. The second organic insulating resin can be a filler-containing resin, regardless of whether the resin is photosensitive or non-photosensitive. Examples of the filler-containing resin may include insulating resins such as photosensitive epoxy or acrylic resins, and insulating resins such as non-photosensitive epoxy resins. The method of forming a reinforcement layer in the case of using a liquid photosensitive resin can be selected from slit coating, curtain coating, die coating, spray coating, electrostatic coating, inkjet coating, gravure coating, screen printing, gravure offset printing, spin coating, and doctor coating. In the case of using a film-like photosensitive resin, lamination, vacuum lamination, vacuum pressing, or the like can be applied.

In the case of the second embodiment, a release layer 53 may be formed, following which an intermediate layer 50 may be formed to improve adhesion between the release layer 53 and a reinforcement layer, and prevent mixing. The material for the intermediate layer 50 can be selected, for example, from nickel, copper, titanium, alloys of these, and multilayers in which two or more of these are used. With these materials, a method selected from plating, vapor deposition, and the like, can be used, but is not limited to this. In the case of providing an intermediate layer 50, the reinforcement layer 68 is formed on the intermediate layer 50.

In this way, using an insulating resin as a reinforcement layer in the wiring board 52, good processability can be achieved, and the entire surface of the substrate excepting the electrical connection portions, such as electrodes, can be covered by the reinforcement layer without any gaps. Thus, the reinforcement layer can effectively suppress occurrence of strain stress in the substrate.

Next, as shown in FIG. 6, the reinforcement layer 68 formed of the second organic insulating resin is patterned to form connection holes therein. If a photosensitive resin is used, the resin can be patterned using photolithography or laser trimming.

Next, a barrier metal layer 63 is formed on the patterned second organic insulating resin. The barrier metal layer 63 can be formed of titanium or copper, or multiple layers of these.

Then, after sputtering copper for serving as a seed layer on the barrier metal layer 63, wiring 64 is formed using electrolytic copper plating. The method of forming wiring is not limited to this, but various known methods may be used.

Next, as shown in FIG. 7, CMP is performed to remove unnecessary barrier metal layer 63 portions and wiring 64 portions deposited on the second organic insulating resin to flatten the wiring layer.

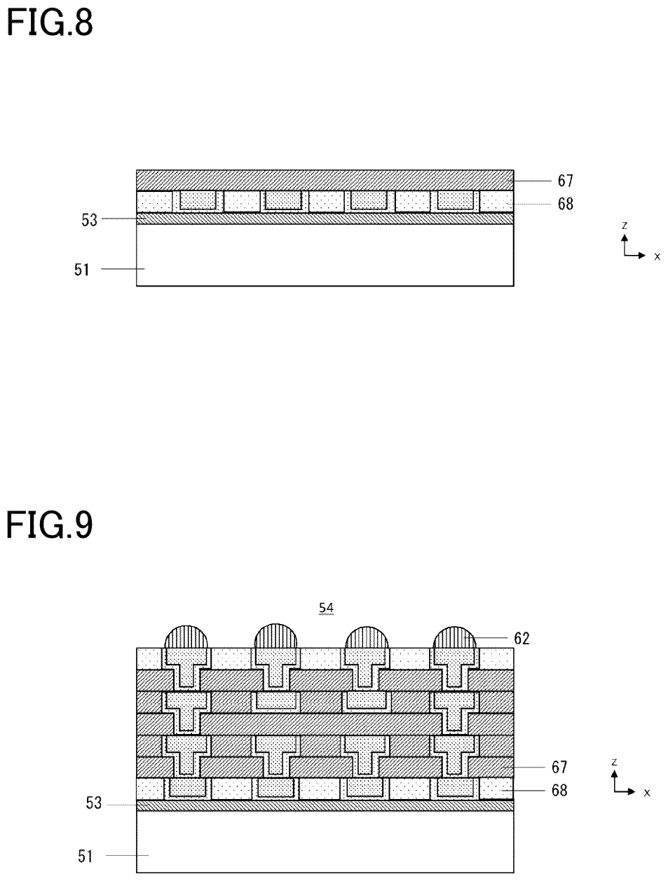

Next, as shown in FIG. 8, a first organic insulating resin is applied onto the surface that has undergone CMP to provide an inner insulating film 67. In FIG. 8, a film containing no filler is used for the inner insulating film 67, which is formed, for example, by spin-coating a photosensitive epoxy resin. Photosensitive epoxy resins can be cured at relatively low temperatures and are less likely to shrink due to curing after formation, and therefore, exhibit good fine pattern formability thereafter.

The method of forming a photosensitive resin in the case of using a liquid photosensitive resin, similarly to a filler-containing organic insulating resin, can be selected from slit coating, curtain coating, die coating, spray coating, electrostatic coating, inkjet coating, gravure coating, screen printing, gravure offset printing, spin coating, and doctor coating.

In the case of using a film-like photosensitive resin, the method can be selected from lamination, vacuum lamination, vacuum pressing, and the like. For the photosensitive organic insulating resin, for example, a photosensitive polyimide resin, photosensitive benzocyclobutene resin, photosensitive epoxy resin, or modified products thereof can be used as an insulating resin.

In the subsequent processes, processes described referring to FIGS. 5 to 8 are repeated to form a wiring board 52. Then, when forming a reinforcement layer 68, a filler-containing second organic insulating resin can be used as necessary similarly to FIG. 5 to complete a substrate 54 with a support as shown in FIG. 3A. If a first organic insulating resin containing no filler is used, a substrate 54 with a support as shown in FIG. 3B can be completed.

The multilayer wiring described above has been formed using a damascene method; however, the method is not limited to this, but a SAP method may be used for the formation.

### Production Method According to Fourth Embodiment

The production method described below is a method in the case where the second insulating resin does not cover part of the wiring board, i.e., in the case where part of the reinforcement layer 68 is open, not covering the entirety.

For example, as shown in FIG. 4B, in the case of using a damascene method, formation of the inner insulating films is followed by application of a photosensitive resist containing no filler, e.g., a plating resist, on the entire surface and, using photolithography, the plating resist pattern is left only in portions not to be covered by the reinforcement layer 68, after which a reinforcement layer 68 is applied to the entire surface of the substrate 54 with a support. Then, the reinforcement layer 68 is patterned using photolithography, laser processing, or the like, which is sequentially followed by plating and CMP to peel off the plating resist, so that a substrate 54 with a support having portions not covered by the reinforcement layer 68 can be formed.

In the case of a SAP method, after applying a reinforcement layer 68, unnecessary portions of the reinforcement layer 68 may be removed.

It should be noted that FIG. 12 shows the substrate 54 with a support shown in FIG. 4B with the semiconductor element and the like 55 mounted thereon and the underfill 59 filled in.

The example shown in FIG. 4C is an example in which a reinforcement layer 68 is formed so as to be in contact with a release layer 53 and, after that, a filling material, e.g., a plating resist 69, that can be easily removed later is filled in advance in portions not covered by the reinforcement layer 68. After that, a substrate 54 with a support may be formed with a method similar to the method described above, and the support 51 may be removed, followed by peeling off the plating resist 69 to provide openings to the wiring board 52, where no reinforcement layer 68 is present.

The method shown in FIG. 4C is a method in which openings where no reinforcement layer 68 is present are provided in advance to the lower surface of the wiring board 52. As another method, a reinforcement layer 68 may be applied to the entire lower surface of the wiring board 52 and, after peeling off the support 51, unnecessary portions of the reinforcement layer 68 may be removed using a laser, trimming, etc. to provide openings where no reinforcement layer 68 is present.

Another example of the production method will be described below, in which part of the reinforcement layer 68 is opened to provide a structure not completely covered by the reinforcement layer 68.

In this method, a semiconductor element and the like 55 are mounted prior to forming a reinforcement layer 68 which is an outermost layer of the wiring board 52, and then the underfill 59 is filled in. After this, a reinforcement layer 68 may be applied using, for example, spin coating or die coating, followed by removing portions of the reinforcement layer 68 from portions serving as the semiconductor element and the like 55 or electrodes, using photolithography. In this case, as shown in FIG. 12, portions of the reinforcement layer 68 can be left on the semiconductor element and the like 55.

Although not shown, a semiconductor element and the like may also be mounted on the lower surface of the wiring board 52 after peeling off the support 51, and the surfaces of the semiconductor element and the like may be covered by a reinforcement layer 68 using similar processing.

### Solder Mounting Processing and the Subsequent Processing in Production Method

Next, as shown in FIG. 9, solder is mounted on the electrodes exposed on the first surface of the substrate 54 with a support. Thus, a substrate 54 with a support as shown in FIG. 1B can be completed. Methods of forming such electrodes include a method of mounting solder and a method of forming copper posts, gold bumps, etc.

Copper post electrodes may be formed on the respective electrodes exposed on the first surface of the substrate 54 with a support, and solder may be deposited on them. Soldering can be performed using a known method, such as a method of printing a solder paste or a method of depositing tin by plating. (Formation of copper post electrodes will be described later.)

Without forming solder electrodes on the respective electrodes exposed on the first surface of the substrate 54 with a support, copper electrodes may be finished with only undergoing surface treatment. Surface treatments such as nickel-gold plating and OSP treatment, for example, can be used.

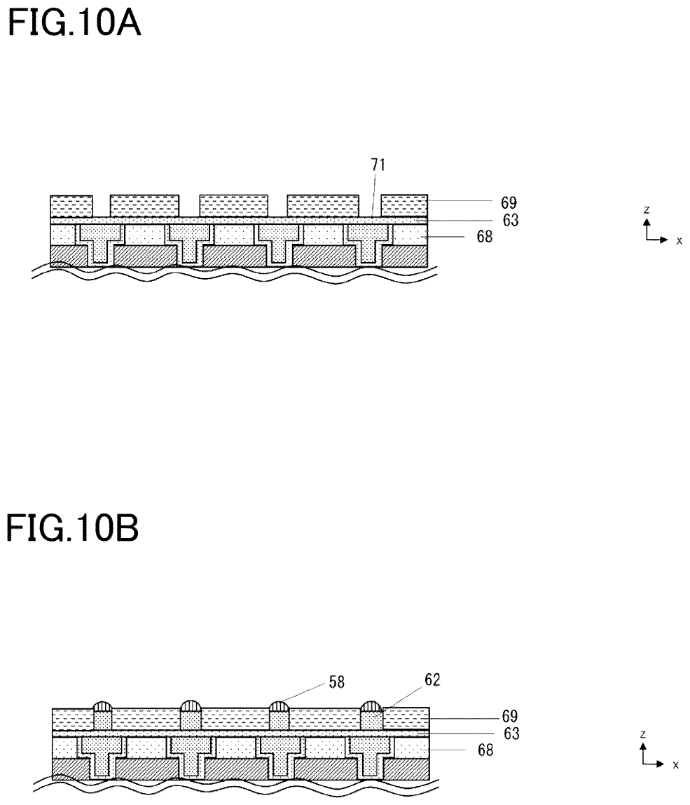

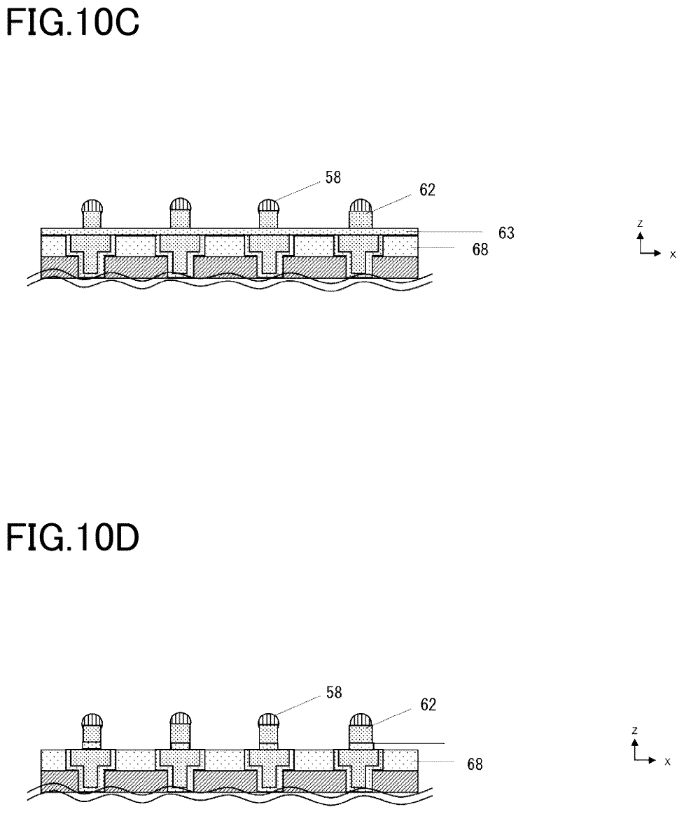

Next, referring to FIGS. 10A-10D, a method of producing copper posts will be described. FIGS. 10A-10D are a set of diagrams illustrating a method in the case of forming copper post electrodes on a first surface 71 of a wiring board 52. In FIGS. 10A-10D, a second surface 72 of the wiring board 52 is omitted.

First, as shown in FIG. 10A, a barrier metal layer 63 is formed on a filler-containing insulating resin, on top of which a plating resist 69 is laminated, and only post electrode portions are opened. Photolithography is used for providing the openings.

Next, as shown in FIG. 10B, electrolytic copper plating is performed using the barrier metal layer 63 as a seed layer, and solder electrodes are formed at the electrode portions by printing or plating.

Next, as shown in FIG. 10C, the plating resist 69 is peeled off and unnecessary barrier metal is removed to complete the copper posts, as shown in FIG. 10D, on the first surface 71 of the wiring board 52.

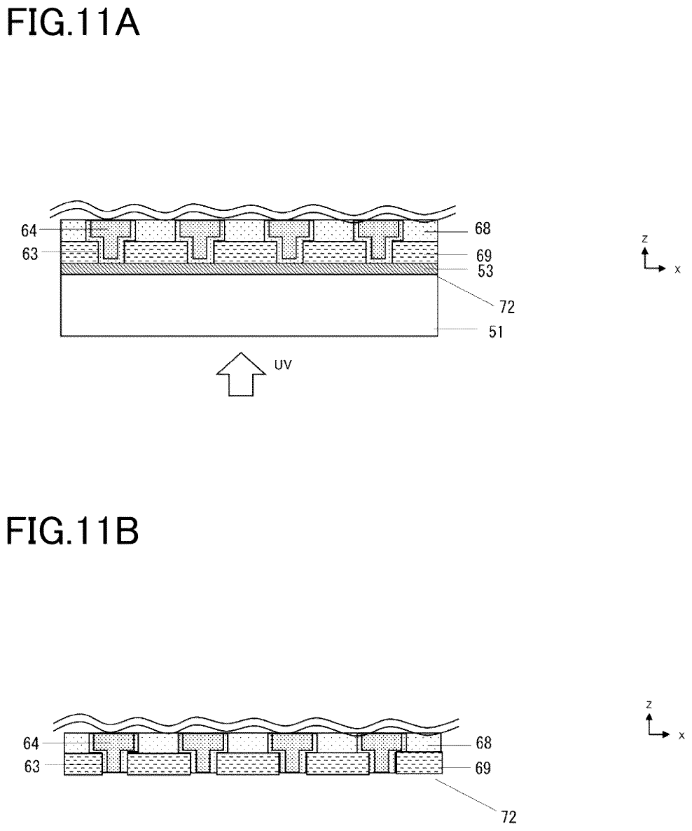

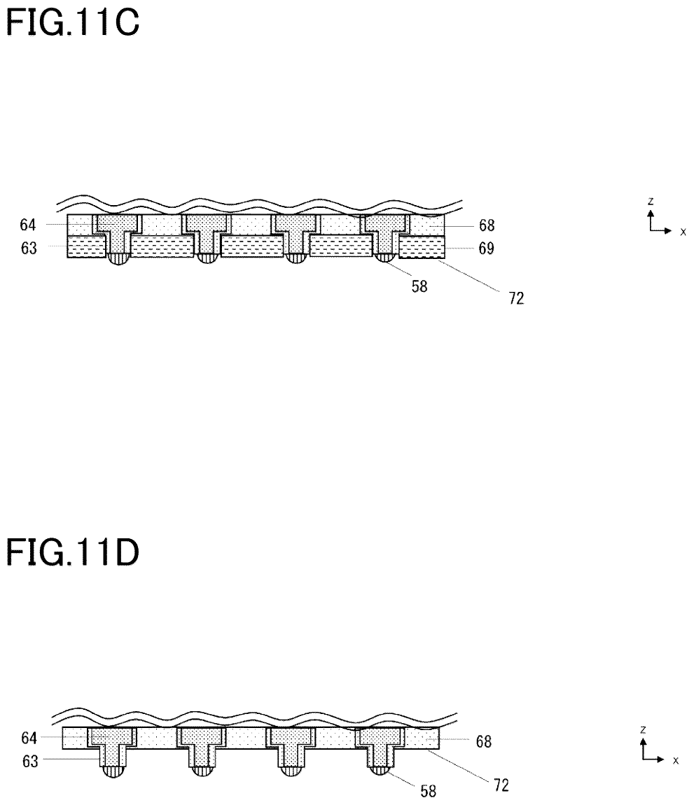

Next, referring to FIGS. 11A-11D, a method of producing copper posts on the second surface 72 of the wiring board 52 will be described. In FIGS. 11A-11D, the first surface 71 of the wiring board 52 is omitted.

When producing copper posts on the second surface 72 of the wiring board 52, a pattern of copper posts is formed first, as shown in FIG. 11A, on a release layer 53, using a plating resist 69. Next, a filler-containing second organic insulating resin is applied as a reinforcement layer to serve as the reinforcement layer 68. In the subsequent processing, lamination is repeated according to the required number as described referring to FIGS. 6 to 8. Then, as shown in FIG. 11A, UV light is applied to release the release layer 53 and the support 51. If an intermediate layer 50 has been formed on the release layer 53, the intermediate layer 50 exposed on the surface is removed using a method such as etching or CMP. After that, as shown in FIG. 11B, portions of the barrier metal layer 63 exposed on the electrode surfaces are removed. Then, as shown in FIG. 11C, solder 58 is formed by printing or plating. Then, as shown in FIG. 11D, the plating resist 69 is removed to complete the copper pillar electrodes.

The substrate 54 with a support or the wiring board 52 completed as described above can be provided with semiconductor elements using the method described referring to FIGS. 1A-1D and 2A-2D.

### Fifth Embodiment

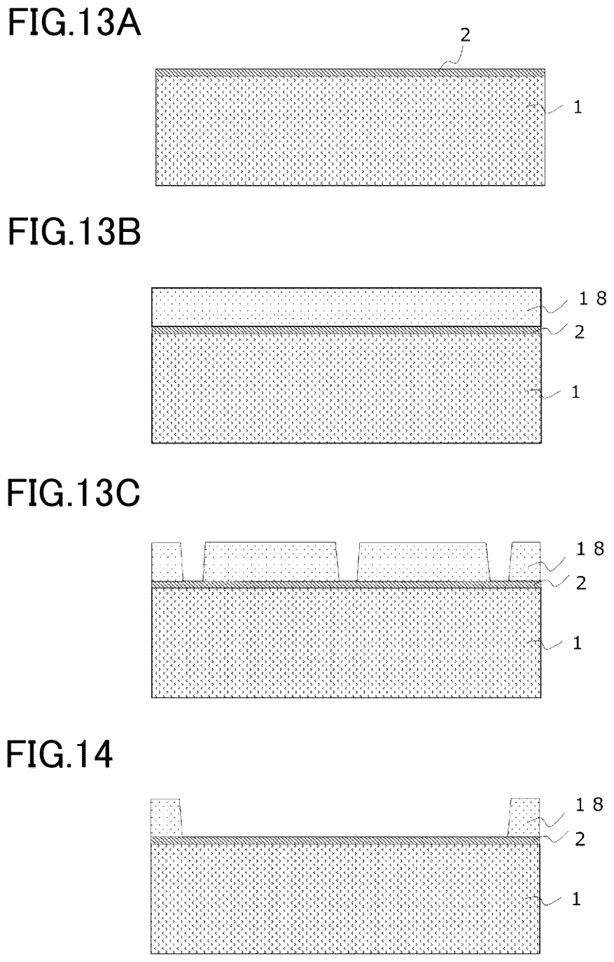

Referring to FIGS. 13A to 20D, an example of production processes of a wiring board using a support according to a fifth embodiment of the present invention will be described.

First, as shown in FIG. 13A, a release layer 2 is formed on a surface of a support 1. The release layer 2 is necessary for releasing the support 1 in a later step.

### First Mode of Forming Connection Holes in Fine Wiring Layer

Next, referring to FIG. 13B to FIG. 13C, a description will be given of a first mode of forming connection holes in a fine wiring layer 19, as a second wiring board. The connection holes are used for forming electrodes to which semiconductor elements are connected. First, as shown in FIG. 13B, a reinforcement layer 18 is formed on the entire upper surface of the release layer 2. The reinforcement layer 18 is made of a filler-containing resin, regardless of whether the resin is photosensitive or non-photosensitive. Examples of the filler-containing resin may include insulating resins such as photosensitive epoxy or acrylic resins, and insulating resins such as non-photosensitive epoxy resins. The method of forming a reinforcement layer in the case of using a liquid photosensitive resin can be selected from slit coating, curtain coating, die coating, spray coating, electrostatic coating, inkjet coating, gravure coating, screen printing, gravure offset printing, spin coating, and doctor coating. In the case of using a film-like photosensitive resin, lamination, vacuum lamination, vacuum pressing, or the like can be applied.

The reinforcement layer is preferred to have a CTE which is lower than that of the resins used for photosensitive resin layers or insulating layers in the second wiring board including fine wiring layers.

Next, connection holes are formed in the reinforcement layer 18 to provide electrodes for establishing an electrical connection with semiconductor elements 15. In order to form the connection holes, the reinforcement layer 18 is patterned as shown in FIG. 13C. In an embodiment of the present invention, openings with a diameter of φ35 μm were formed in the reinforcement layer 18. Patterning can be performed using, for example, photolithography techniques or laser processing techniques.

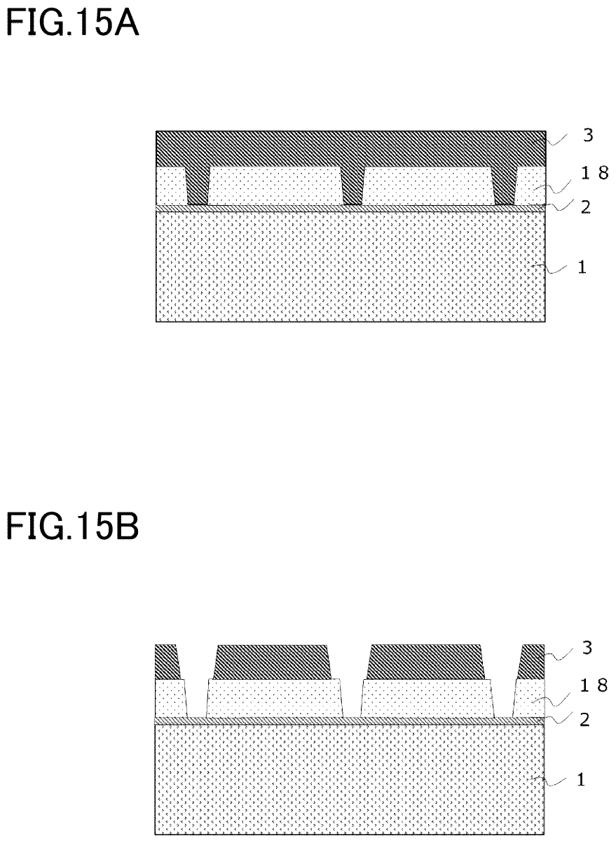

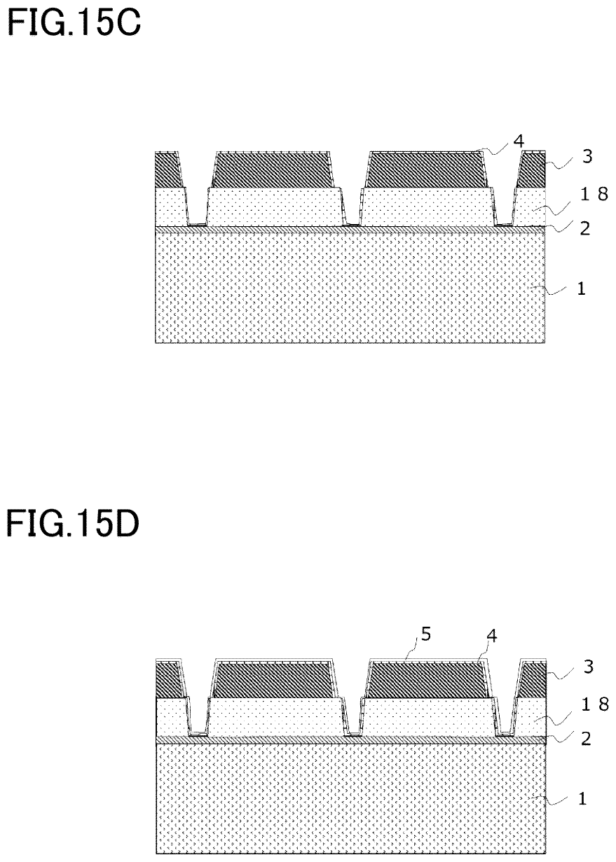

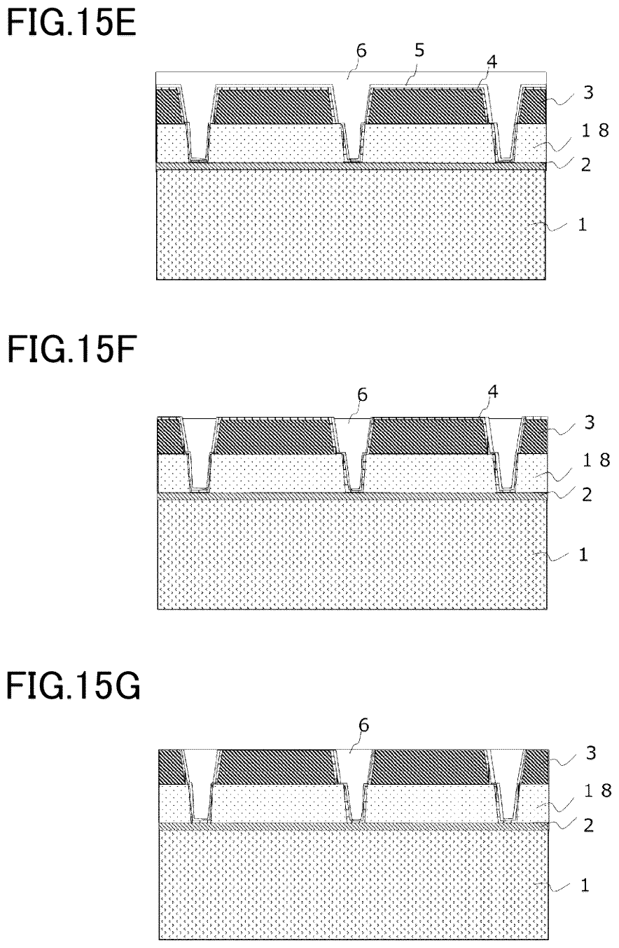

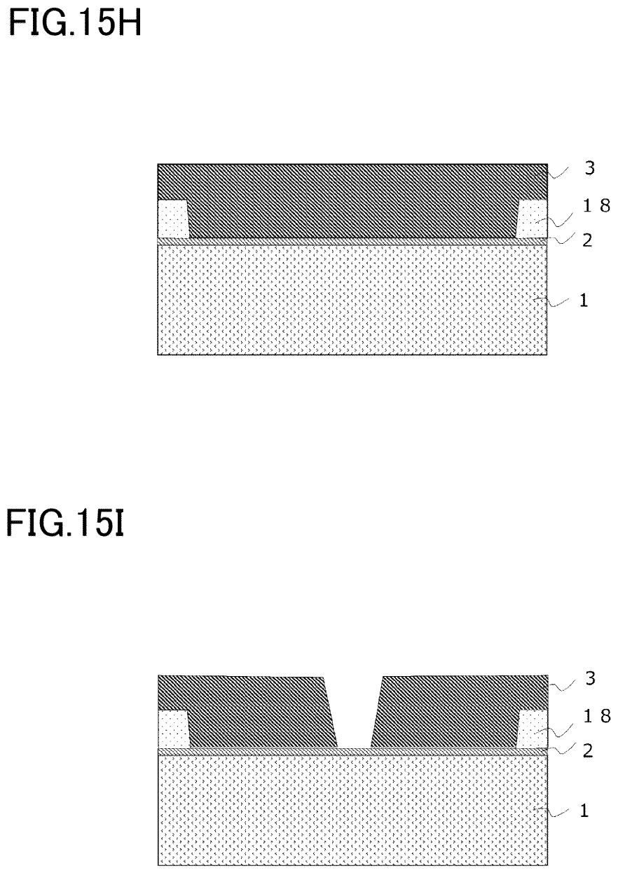

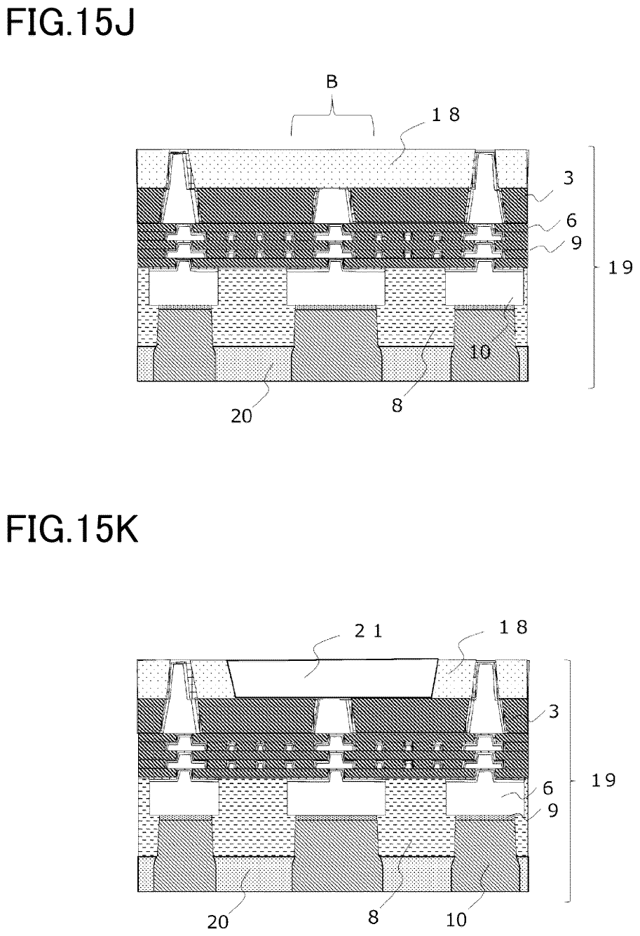

Next, as shown in FIG. 15A, a photosensitive resin layer 3 is formed on the upper surface of the patterned reinforcement layer 18. The photosensitive resin layer 3 of the present embodiment is formed, for example, by spin-coating a photosensitive epoxy resin. Photosensitive epoxy resins can be cured at relatively low temperatures, and are less likely to shrink due to curing after formation, and therefore, exhibit good fine pattern formability thereafter.

Similarly to the reinforcement layer 18, the method of forming a photosensitive resin in the case of using a liquid photosensitive resin can be selected from slit coating, curtain coating, die coating, spray coating, electrostatic coating, inkjet coating, gravure coating, screen printing, gravure offset printing, spin coating, and doctor coating. In the case of using a film-like photosensitive resin, lamination, vacuum lamination, vacuum pressing, or the like can be applied.

For the photosensitive resin layer 3, for example, a photosensitive polyimide resin, photosensitive benzocyclobutene resin, photosensitive epoxy resin, or modified products thereof can be used as an insulating resin.

As a result of studying photosensitive resins and insulating resins suitable for forming fine wiring, it was found that the range of CTE at which fine wiring can be formed was around 50 to 80 ppm/K.

Next, as shown in FIG. 15B, openings are formed in the photosensitive resin layer 3 using photolithography. These openings are formed to match the respective openings formed in the reinforcement layer 18. The openings may be subjected to plasma treatment for the purpose of removing residues produced during development. The thickness of the photosensitive resin layer 3 is determined according to the thickness of the conductor layer portions formed in the openings, and is determined to be 7 μm, for example, in an embodiment according to the present invention. The shape of the openings in plan view is determined according to the pitch and shape of the junction electrodes of the semiconductor elements. In an embodiment according to the present invention, openings with a diameter of 445 μm are formed.

### Second Mode of Forming Connection Holes in Fine Wiring Layer

Next, referring to FIGS. 14, 15H and 15I, a description will be given of a second mode of forming connection holes in a photosensitive resin layer 3 without them passing through a reinforcement layer 18.

In the first mode of forming connection holes in a fine wiring layer, as described referring to FIGS. 13B, 13C, and 15A to 15B, the reinforcement layer 18 is formed on the release layer 2 to cover substantially the entire surface excepting the regions where the openings of the photosensitive resin layer 3 are formed. In the first mode, the openings formed in the photosensitive resin layer 3 match the respective openings formed in the reinforcement layer 18, and reach the release layer 2 to serve as connection holes.

However, in the second mode of forming a connection hole in a fine wiring layer, the reinforcement layer 18 formed on the support 1 or the release layer 2 does not necessarily cover substantially the entire surface excepting the regions where the openings of the photosensitive resin layer 3 are formed. In other words, not all the openings formed in the photosensitive resin layer 3 have to match the openings formed in the reinforcement layer 18, but part of the openings formed in the photosensitive resin layer may reach the release layer 2 without them passing through the reinforcement layer 18.

The second mode of forming connection holes in a fine wiring layer will be described in detail.

First, FIG. 14 is a cross-sectional view showing a state in which the reinforcement layer is patterned in the second form of connection hole formation in the fine wiring layer. The steps leading to FIG. 14 are the same as the steps leading to FIGS. 1A to 13B. and 14 is different from the case of FIG. 13C in that the reinforcing layer 18 is not formed in almost the entire area of the photosensitive resin layer 3 other than where the opening is formed. In other words, in FIG. 14, even in the regions where the openings of the photosensitive insulating resin 3 are formed, there are locations where the reinforcing layer 18 is not formed.

Next, referring to FIG. 15H, forming a photosensitive resin layer 3 in the second mode of forming connection holes in a fine wiring layer will be described.

FIG. 15H is a cross-sectional view illustrating a state in which a photosensitive resin layer 3 has been formed using a method similar to the method described referring to FIG. 15A.

Next, referring to FIG. 15I, pattern forming of the photosensitive resin layer 3 in the second mode of forming connection holes in a fine wiring layer will be described.

FIG. 15I is a cross-sectional view illustrating a state in which the photosensitive resin layer 3 has been patterned using a method similar to the method described referring to FIG. 15B.

According to the second mode of forming connection holes in a fine wiring layer, connection holes formed in the photosensitive resin layer 3 are open only in the photosensitive resin layer 3, as shown in FIG. 15I, without them passing through the reinforcement layer 18. Therefore, connection holes, which are formed depending on the patterning accuracy of the photosensitive resin layer 3, can be beneficially formed with ease with a minute opening diameter, compared to the connection holes formed passing through the reinforcement layer 18.

### Third Mode of Forming Connection Holes in Fine Wiring Layer

Next, referring to FIGS. 15J and 15K, a description will be given of a third mode of forming connection holes in a photosensitive resin layer 3 without them passing through a reinforcement layer 18.

FIG. 15J shows an example of a cross section of the region enclosed by the border A-A′ indicated in FIG. 20C in a wiring layer 19 which has been formed using a damascene method and fixed to a wiring board unit 14. In FIG. 15J, no opening is formed in the reinforcement layer 18 in the region B which is one of the regions to provide connection holes. In order to form a connection hole in the region B, an opening 21 is formed, as shown in FIG. 15K, in the reinforcement layer 18. Then, using processes similar to the processes in the second mode of forming connection holes in a fine wiring layer shown in FIGS. 15H and 15I, a photosensitive resin layer 3 can be embedded in the opening 21, followed by forming a connection hole.

In the case of this formation also, connection holes are formed depending on the patterning accuracy of the photosensitive resin layer 3, and therefore, can be beneficially formed with ease with a minute opening diameter, compared to connection holes formed passing through the reinforcement layer 18.

### Formation of Seed Adhesion Layer and Seed Layer

Next, referring to FIGS. 15C and 15D, processes of forming a seed adhesion layer and a seed layer will be described. The following description will be provided according to the first mode of forming a reinforcement layer, and unless particularly mentioned, processes of forming a seed adhesion layer and a seed layer and the subsequent processes can be performed using similar processes even when the second mode of forming a reinforcement layer is used.

First, as shown in FIGS. 15C and 15D, a seed adhesion layer 4 and a seed layer 5 are formed in a vacuum. The seed adhesion layer 4 enhances adhesion of the seed layer 5 to the photosensitive resin layer 3 and prevents peeling of the seed layer 5. The seed layer 5 serves as a power supply layer for electroplating when forming wiring. The seed adhesin layer 4 and the seed layer 5 are formed, for example, using sputtering or vapor deposition, and using, for example, Cu, Ni, Al, Ti, Cr, Mo, W, Ta, Au, Ir, Ru, Pd, Pt, AlSi, AlSiCu, AlCu, NiFe, ITO, IZO, AZO, ZnO, PZT, TiN, Cu₃N₄, or a Cu alloy, or combinations thereof. In the present invention, a titanium layer as the seed adhesion layer 4 and a copper layer as the seed layer 5 are sequentially formed using sputtering, from the perspective of electrical characteristics, case of production, and cost. The total thickness of the titanium layer and the copper layer is preferred to be 1 μm or less as a power supply layer for electroplating. In an embodiment of the present invention, Ti: 50 nm and Cu: 300 nm are formed.

### Formation of Conductor Layer

Next, as shown in FIG. 15E, a conductor layer 6 is formed using electroplating. The conductor layer 6 will be formed into electrodes for establishing a connection with the semiconductor clements 15. Nickel electroplating, copper electroplating, chromium electroplating, Pd electroplating, gold electroplating, rhodium electroplating, iridium electroplating, or the like can be used; however, from the perspective of case, cost, and electrical conductivity, copper electroplating is preferred. The thickness of the copper electroplating is preferred to be 1 μm or more from the perspective of serving as electrodes for connection with the semiconductor elements 15 and solder bonding and is preferred to be 30 μm or less from the perspective of productivity. In an embodiment of the present invention, Cu: 9 μm is formed in the openings of the photosensitive resin layer 3, and Cu: 2 μm is formed on the photosensitive resin layer 3.

Next, as shown in FIG. 15F, the copper layer is polished using chemical mechanical polishing (CMP) processing or the like to remove portions of the conductor layer 6 and seed layer 5. The polishing processing can be performed so that the seed adhesion layer 4 portions and the conductor layer 6 portions can form a surface. In an embodiment of the present invention, Cu: 2 μm of the conductor layer 6 on the photosensitive resin layer 3 and Cu: 300 nm of the seed layer 5 are polished away.

Next, as shown in FIG. 15G, portions of the seed adhesion layer 4 and photosensitive resin layer 3 are removed using polishing such as CMP processing again. Since the polishing is performed for the different materials of the seed adhesion layer 4 and the photosensitive resin layer 3, chemical polishing is less effective but physical polishing using an abrasive is the predominant method. Therefore, for the purpose of simplifying processing, the seed adhesion layer 4 and the photosensitive resin layer 3 may be polished in a single process, or, for the purpose of increasing polishing efficiency, the polishing method may be changed depending on the materials of the seed adhesion layer 4 and the photosensitive resin layer 3. Thus, the conductor layer 6 portions remaining after the polishing serve as electrodes for establishing a connection with the semiconductor elements 15.

### Formation of Multilayer Wiring Layer

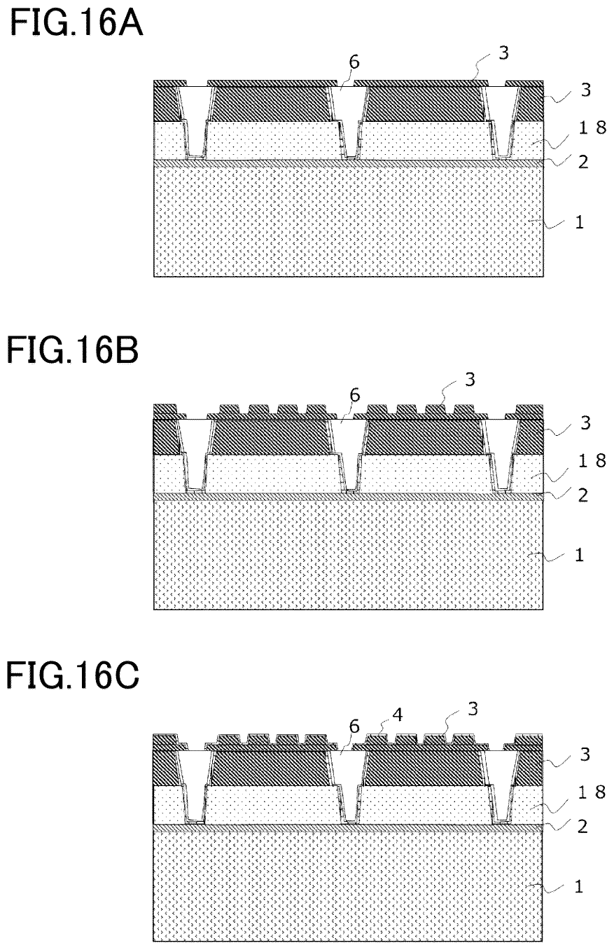

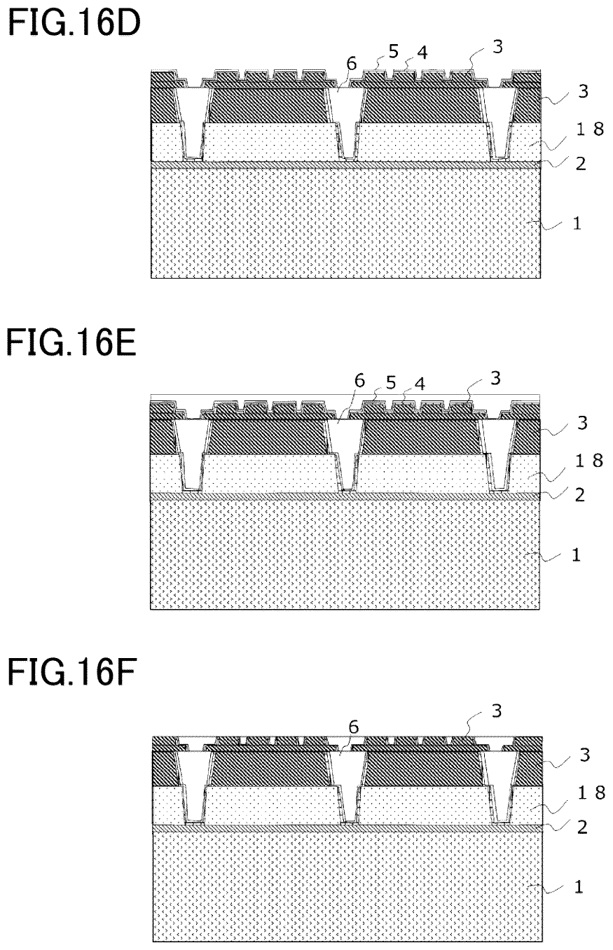

Next, as shown in FIG. 16A, a photosensitive resin layer 3 is formed on the upper surface as in FIGS. 15A and 15B. The thickness of the photosensitive resin layer 3 is determined according to the thickness of the conductor layer portions formed in the openings, and is determined to be 2 μm, for example, in an embodiment of the present invention. The shape of the openings in plan view is determined from the perspective of connection with the conductor layer 6 portions. According to an embodiment of the present invention, the openings are formed with a diameter, for example, of 10 μm. These openings each have a shape of a via connecting between the overlayer and the underlayer of multilayer wiring.

As shown in FIG. 16B, further, a photosensitive resin layer 3 is formed on the upper surface as in FIGS. 15A and 15B. The thickness of the photosensitive resin layer 3 is determined according to the thickness of the conductor layer portions formed in the openings, and is determined to be 2 μm, for example, in an embodiment of the present invention. The shape of the openings in plan view is determined from the perspective of connectivity of the laminate. Thus, the openings are formed enclosing the outer side of the respective openings of the underlayer. In an embodiment of the present invention, openings with a diameter of φ20 μm, for example, are formed. These openings each have a shape of part of a via connecting the wiring section of the multilayer wiring with the overlayer and the underlayer.

Next, as shown in FIGS. 16C and 16D, a seed adhesion layer 4 and a seed layer 5 are formed in a vacuum as in FIGS. 15C and 15D. In an embodiment of the present invention, Ti: 50 nm and Cu: 300 nm are formed.

Next, as shown in FIG. 16E, a conductor layer 6 is formed using electroplating. The conductor layer 6 serves as vias and a wiring section. Nickel electroplating, copper electroplating, chromium electroplating, Pd electroplating, gold electroplating, rhodium electroplating, iridium electroplating, or the like can be used; however, from the perspective of ease, cost, and electrical conductivity, copper electroplating is preferred. The thickness of copper electroplating is preferred to be 0.5 μm or more from the perspective of electrical resistance of the wiring section and is preferred to be 30 μm or less from the perspective of productivity. According to an embodiment of the present invention, Cu: 6 μm is formed in the double-openings of the photosensitive resin layer 3, Cu: 4 μm is formed in the single-openings of the photosensitive resin layer 3, and Cu: 2 μm is formed on the photosensitive resin layer 3 portions.

Next, as shown in FIG. 16F, chemical mechanical polishing (CMP) processing or the like is performed to remove portions of the conductor layer 6 and seed layer 5. Subsequently, portions of the seed adhesion layer 4 and photosensitive resin layer 3 are removed using polishing such as CMP processing again. Thus, the conductor layer 6 portions remaining after the CMP processing or the like serve as conductors for the vias and the wiring section. In an embodiment of the present invention, Cu: 2 μm of the conductor layer 6 on the photosensitive resin layer 3 and Cu: 300 nm of the seed layer 5 are polished away.

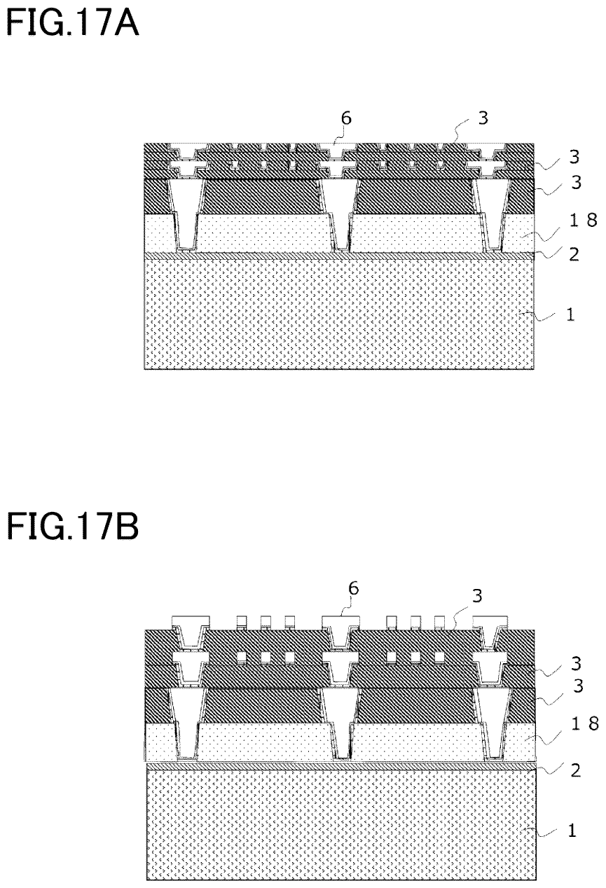

As shown in FIG. 17A, multilayer wiring is formed repeating the processes shown in FIGS. 16A to 16F.

In an embodiment of the present invention, two wiring layers are formed. Although a damascene method is used in the multilayer wiring formation shown in FIGS. 16A to 17A, the present invention should not be limited to this, but can be applied to the multilayer wiring board formed using a SAP method as shown in FIG. 17B.

### Formation of Junction Electrodes

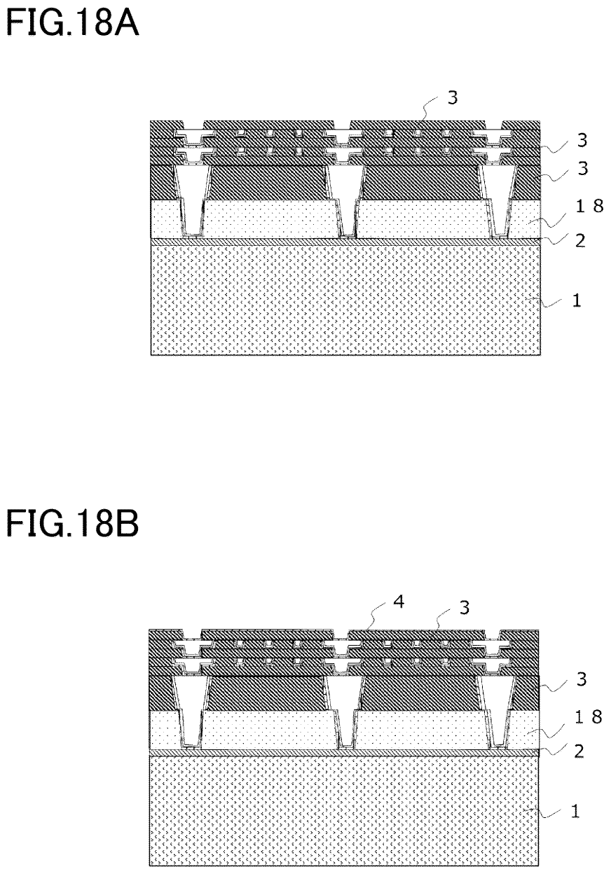

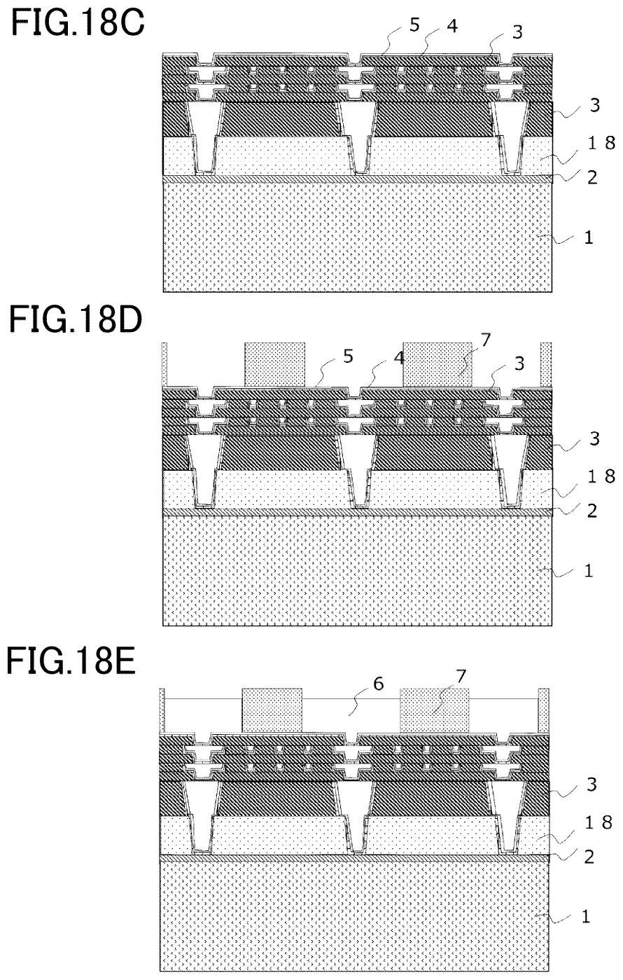

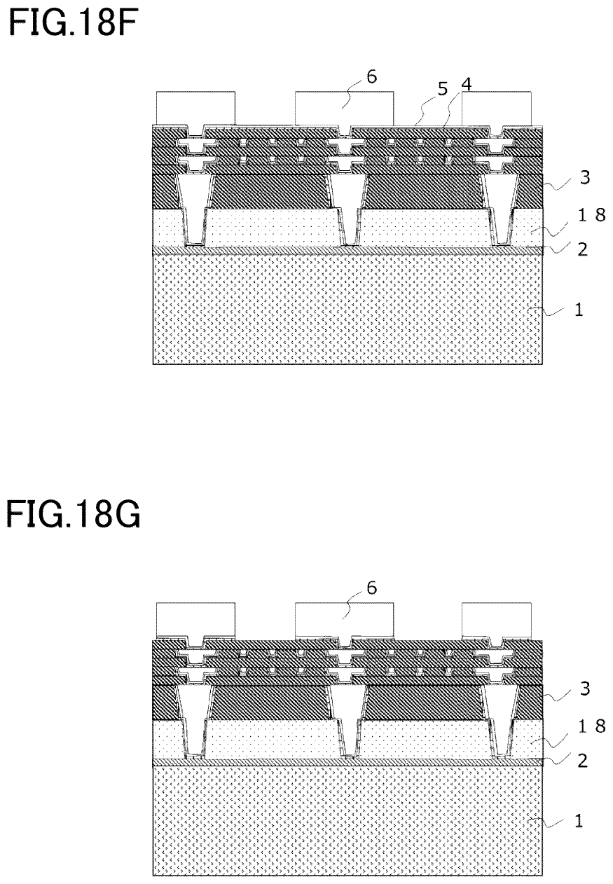

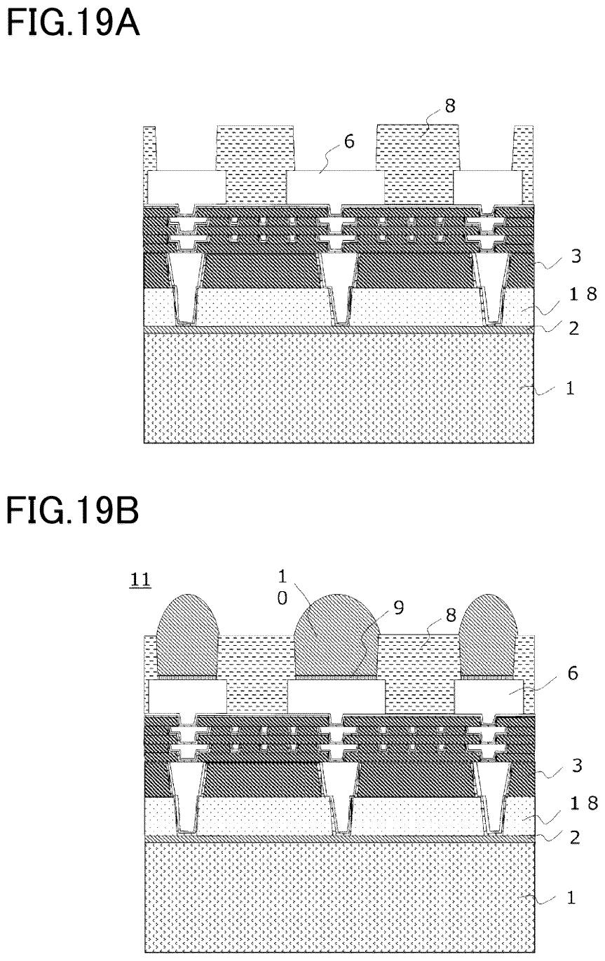

Next, referring to FIGS. 18A to 19B, processes of forming junction electrodes to an FC-BGA substrate 12 as a first wiring board will be described. When forming junction electrodes, a photosensitive resin layer 3 is formed, as shown in FIG. 18A, on the upper surface as in FIG. 16A.

Next, as shown in FIGS. 18B and 18C, a seed adhesion layer 4 and a seed layer 5 are formed in a vacuum as in FIGS. 15C and 15D.

Next, as shown in FIG. 18D, a resist pattern 7 is formed. After that, as shown in FIG. 18E, a conductor layer 6 is formed using electroplating. The conductor layer 6 serves as electrodes for establishing a connection with the FC-BGA substrate 12. The thickness of copper electroplating is preferred to be 1 μm or more from the perspective of solder bonding and is preferred to be 30 μm or less from the perspective of productivity. According to an embodiment of the present invention, Cu: 9 μm is formed in the openings of the photosensitive resin layer 3, and Cu: 7 μm is formed on the photosensitive resin layer 3.

After that, as shown in FIG. 18F, the resist pattern 7 is removed. After that, as shown in FIG. 18G, unnecessary portions of the seed adhesion layer 4 and seed layer 5 are etched away. The conductor layer 6 portions remaining on the surface in this state serve as electrodes for establishing a connection with the FC-BGA substrate 12.

Next, as shown in FIG. 19A, a solder resist layer 8 is formed. The solder resist layer 8 is formed covering the photosensitive resin layer 3 using exposure and development so as to provide openings in which the conductor layer 6 portions are exposed. As materials for the solder resist layer 8, for example, insulating resins such as epoxy resins and acrylic resins can be used. According to an embodiment of the present invention, the solder resist layer 8 is made of a filler-containing photosensitive epoxy resin.

Next, as shown in FIG. 19B, a surface treatment layer 9 is provided to prevent oxidation of the surface of the conductor layer 6 and enhance wettability of solder bumps. In an embodiment of the present invention, the surface treatment layer 9 is formed using Ni/Pd/Au electroless plating. It should be noted that an OSP (surface treatment using organic solderability preservative water-soluble preflux) film may be formed as the surface treatment layer 9. Plating may be appropriately selected from tin electroless plating, Ni/Au electroless plating, and other electroplating methods according to the application. Next, a solder material is placed on the surface treatment layer 9 portions, followed by melting and cooling for fixture to thereby form solder joints 10. Thus, a wiring board 11 formed on the support 1 is completed.

### Joining of Wiring Board, Peeling of Support, and Mounting of Elements

Next, referring to FIGS. 20A to 20D, processes for joining of wiring board, peeling of support, and mounting of elements will be described.

First, as shown in FIG. 20A, the substrate 11 with a support is joined with the FC-BGA substrate 12 that is a first wiring board, and then the joints are sealed with an underfill layer 20. The underfill layer 20 is made of, for example, a resin selected from an epoxy resin, urethane resin, silicone resin, polyester resin, oxetane resin, and maleimide resin, or a mixture of two or more of these resins, with an addition of silica, titanium oxide, aluminum oxide, magnesium oxide, zinc oxide or the like as a filler. The underfill layer is formed by filling a liquid resin.

Then, as shown in FIG. 20B, the support 1 is peeled off. The release layer 2 is brought into a peelable state by applying laser light 13. The laser light 13 is applied to the release layer 2 formed at the interface with the support 1, from one side of the support 1 facing away from the FC-BGA substrate 12, to bring the release layer 2 into a peelable state so that the support 1 can be detached. Next, after removing the support 1 as shown in FIG. 20C, the release layer 2, the seed adhesion layer 4, and the seed layer 5 are removed to obtain a wiring board unit 14 including a fine wiring board 19 that is a second wiring board.

After that, semiconductor elements 15 are mounted, as shown in FIG. 20D, to complete a semiconductor device 16. In this case, prior to mounting the semiconductor elements 15, the conductor layer 6 exposed to the surface may be surface-treated using Ni/Pd/Au electroless plating, OSP, tin electroless plating, Ni/Au electroless plating, or the like to prevent oxidation and enhance wettability of the solder bumps. Through these processes, a semiconductor device 16 is completed.

### Sixth Embodiment

### Intermediate Layer

Next, referring to FIGS. 22 to 24, a sixth embodiment will be described.

The sixth embodiment is different from the first embodiment in that an intermediate layer 50 is provided between the release layer 2 and the reinforcement layer 18. In the following description, identical reference signs are given to components that are the same as or equivalent to those in the fifth embodiment to simplify or omit repeated description.

In the sixth embodiment, as shown in FIG. 22, after forming a release layer 2, which is necessary for peeling the support 1 in a later process, on one surface of the support 1, a seed adhesion layer 4 and a seed layer 5 are formed as an intermediate layer 50.

The specific method or materials described referring to FIGS. 15C and 15D can be used for forming the seed adhesion layer 4 and the seed layer 5.

Provision of such an intermediate layer 50 can improve adhesion between the release layer 2 and the reinforcement layer 18 which will be formed in a later process.

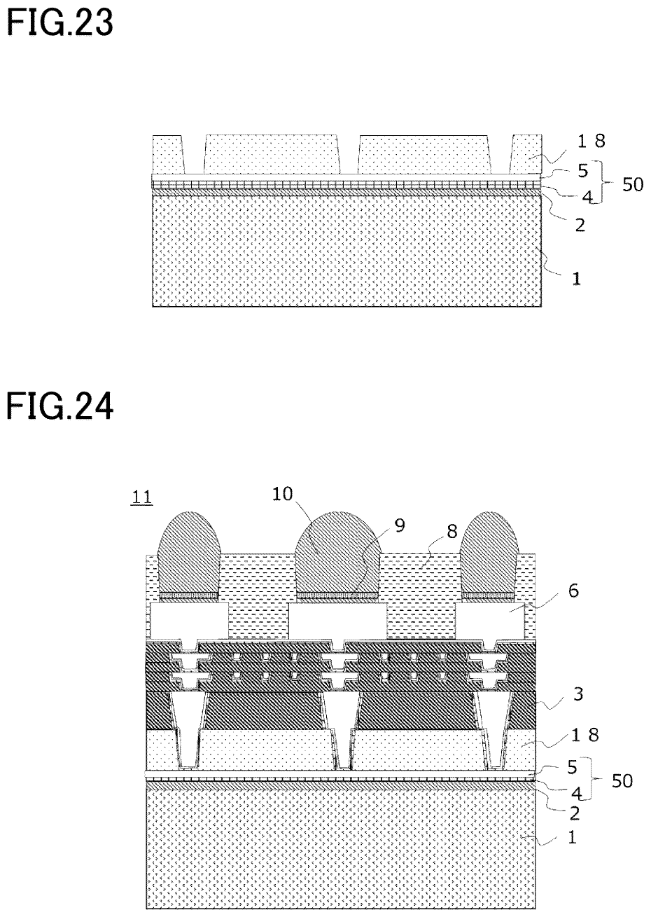

Next, referring to FIG. 23, patterning of the reinforcement layer 18 will be described. In the sixth embodiment, after forming the reinforcement layer 18 shown in FIG. 22, a pattern for the reinforcement layer 18 is formed on the upper surface of the intermediate layer 50 using a method similar to the method used in the fifth embodiment.

Next, referring to FIG. 24, a state in which a surface treatment layer and solder joints are formed to complete a substrate with a support according to the sixth embodiment.

In the sixth embodiment also, after patterning the reinforcement layer 18, a substrate with a support shown in FIG. 24 can be obtained using processes similar to those of the fifth embodiment described referring to FIGS. 15A to 19B.

After this, the support 1 is peeled from the substrate with a support shown in FIG. 24, using processes similar to those of the fifth embodiment described referring to FIGS. 20A to 20C. However, in the sixth embodiment, provision of the intermediate layer 50 can prevent the support 1 from being peeled off before being removed. Also, intermixing of the release layer 2 and the photosensitive resin layer 3 can be prevented.

After removing the support 1, the seed adhesion layer 4 and the seed layer 5 configuring the intermediate layer 50 can be etched away.

### Evaluation of First Embodiment

Next, the semiconductor device of the first embodiment shown in FIG. 2D was prepared to evaluate the effects of using the configuration in the production method and of using the production method of the first embodiment. The wiring boards used for the evaluation had an inner structure in which reinforcement layers were provided on respective both surfaces (FIG. 3A) and an inner structure in which a reinforcement layer was provided on one surface (FIG. 3B), as shown in FIGS. 3A-3D. The reinforcement layers were prepared according to the evaluation conditions shown in Table 1.

TABLE 1

| | Thickness of | CET of | |
|---|---|---|---|
| | reinforcement | reinforcement | |
| | layer | layer | Processing |
| | (μm) | (ppm/K) | method |
| Evaluation Condition 1 | 45 | 9 | Damascene |
| Evaluation Condition 2 | 45 | 19 | Damascene |
| Evaluation Condition 3 | 45 | 28 | Damascene |
| Evaluation Condition 4 | 45 | 39 | Damascene |
| Evaluation Condition 5 | 45 | 9 | SAP |
| Evaluation Condition 6 | 30 | 9 | Damascene |
| Evaluation Condition 7 | 30 | 19 | Damascene |
| Evaluation Condition 8 | 30 | 28 | Damascene |
| Evaluation Condition 9 | 30 | 39 | Damascene |
| Evaluation Condition 10 | 15 | 9 | Damascene |
| Evaluation Condition 11 | 15 | 19 | Damascene |
| Evaluation Condition 12 | 15 | 28 | Damascene |
| Evaluation Condition 13 | 15 | 39 | Damascene |
| Evaluation Condition 14 | 60 | 9 | Damascene |
| Evaluation Condition 15 | 60 | 19 | Damascene |
| Evaluation Condition 16 | 60 | 28 | Damascene |
| Evaluation Condition 17 | 60 | 39 | Damascene |

In each of evaluation examples and comparative examples, a conductor pattern of width 1,000 μm was formed as an outermost layer (as indicated by X in FIGS. 3A and 3B) so that cracking would easily occur to observe cracking improvement effects of the reinforcement layers.

Herein, the thickness of each reinforcement layer was as indicated by Z in FIG. 3A.

### Comparative Examples

In each of the comparative examples, an organic insulating resin containing no filler was used as the first organic insulating resin in the insulating film of the surface layer.

For the configurations with Evaluation Conditions 1 to 5 and the comparative examples, via connection reliability testing was conducted. The via connection reliability testing was conducted according to the following conditions. The criteria for passing were the rate of change in resistance being ±3%, and cracking and delamination not occurring.

Standard: JESD22-A106B (Condition D)
Temperature: −65° C./5 min ⇒ Ambient temperature/1 min → 150° C./5
min

### Confirmation of Effects

Before failing in the via connection reliability testing, the configurations with Evaluation Conditions 1 to 17 could undergo 1,000 to 2,000 testing cycles, but the comparative examples could undergo only 300 to 500 testing cycles. By forming the filler-containing organic insulating resin layers of the present invention on top and bottom of the fine wiring layer, stress inside the wiring layer could be relieved, and cracking originating from areas where stress was concentrated became less likely to occur, effectively exerting via connection reliability.

Since the CTE of the photosensitive insulating resin in which fine wiring could be formed was in the range of around 50 to 80 ppm/K, it can be said that the reinforcement layers could exert effects with a CTE of around 40 ppm/K lower than that of the photosensitive insulating resin.

It is considered that, since the volume of the reinforcement layers with a CTE lower than that of the photosensitive insulating resin increases by increasing the thickness of the reinforcement layer to 45 μm or greater, stress strain can be further reduced in the insulating resin and crack resistance can be further improved. It is also considered that, although the effects are reduced by reducing the thickness of the reinforcement layers to less than 45 μm, crack resistance can still be improved compared to the comparative examples with no reinforcement layers.

Since the results of Evaluation Condition 5 were equivalent to those of other evaluation conditions, it can be said that there is no great difference in crack resistance between the wiring formed using a damascene method and the wiring formed using a SAP method, although these methods are different from each other.

Furthermore, the results of the evaluation conditions with the reinforcement layers provided on both respective surfaces were equivalent to those of the evaluation conditions with the reinforcement layer provided on only one surface, and therefore, it can be said that there is no great difference in crack resistance whether the reinforcement layer was provided on each of both surfaces or on only one surface.

### Evaluation of Fifth Embodiment

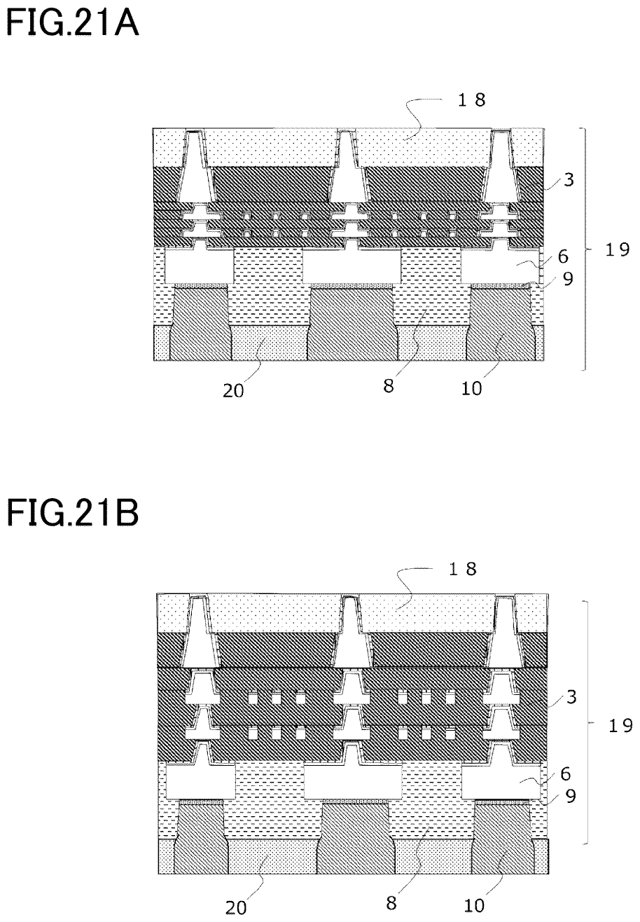

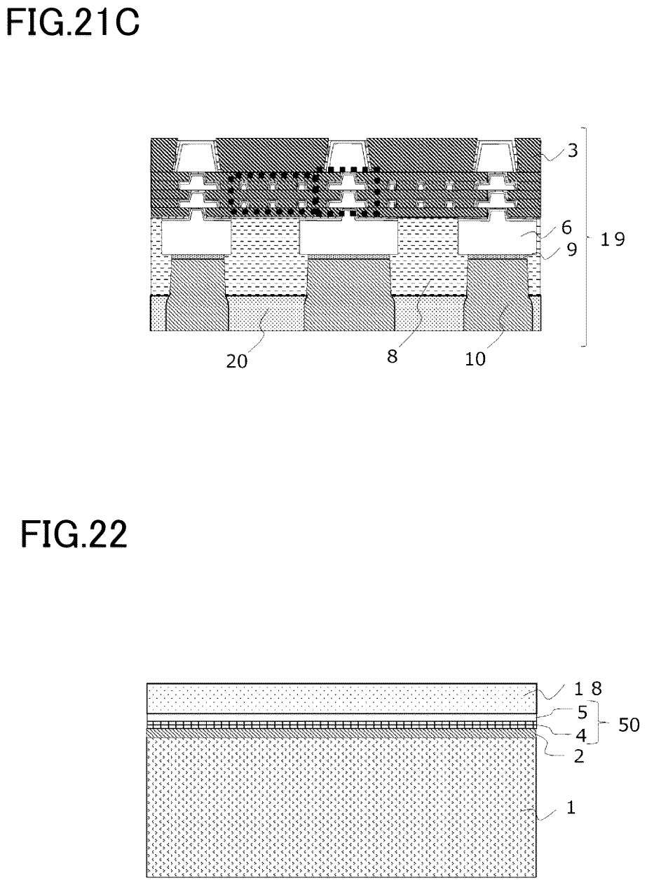

Next, the effects of using the configuration of the wiring board unit 14 of the fifth embodiment shown in FIG. 20C and the production method thereof will be described. The following evaluations for the wiring board unit 14 shown in FIG. 20C were obtained as a result of measuring reinforcement layers prepared as in the first embodiment under the evaluation conditions shown in Table 1. FIGS. 21A and 21B are cross-sectional views illustrating the region enclosed by the border A-A′ indicated in FIG. 20C in the wiring board unit 14.

As comparative examples, wiring layers in which no reinforcement layers 18 were formed in the processes shown in FIGS. 13A to 20C were prepared. A cross section of a region similar to FIGS. 21A or 21B is shown in FIG. 21C.

In each of evaluation examples and comparative examples, a conductor pattern of width 1,000 μm was formed as an outermost layer so that cracking would easily occur in the fine wiring layer 19 of the wiring board unit 14 to examine cracking improvement effects of the reinforcement layers 18.

### Comparative Examples

Comparative examples were prepared under conditions similar to Evaluation Conditions 1 to 4 except that no reinforcement layers 18 were formed as outermost layers of the fine wiring layer 19 of the wiring board unit 14. The method used for forming the fine wiring layers was a damascene method.

### Reinforcement Layers: None

For the configurations with Evaluation Condition 1 to the comparative examples, via connection reliability testing was conducted.

The via connection reliability testing was conducted according to the following conditions. The criteria for passing were the rate of change in resistance being ±3%, and cracking and delamination not occurring.

Standard: JESD22-A106B (Condition D)
Temperature: −65° C./5 min ⇒ Ambient temperature/1 min → 150° C./5
min

### Confirmation of Effects

Before failing in the via connection reliability testing, the configurations with Evaluation Conditions 1 to 17 could undergo 1,000 to 2,000 testing cycles, but the comparative examples could undergo only 300 to 500 testing cycles. By forming the reinforcement layers 18 of the present invention as outermost layers of the fine wiring layer 19 of the wiring board unit 14, stress inside the wiring layer could be relieved, and cracking originating from areas where stress was concentrated became less likely to occur, which had an effect on via connection reliability.

Since the CTE of the photosensitive insulating resin in which fine wiring could be formed was in the range of around 50 to 80 ppm/K, it can be said that the reinforcement layers could exert effects with a CTE of around 40 ppm/K lower than that of the photosensitive insulating resin.

It is considered that, since the volume of the reinforcement layers with a CTE lower than that of the photosensitive insulating resin increases by increasing the thickness of the reinforcement layer to 45 μm or greater, stress strain can be further reduced in the insulating resin and crack resistance can be further improved. It is also considered that, although the effects are reduced by reducing the thickness of the reinforcement layers to less than 45 μm, crack resistance can still be improved compared to the comparative examples with no reinforcement layers.

In other words, in the present embodiment, the second wiring board configured using high-CTE materials is sandwiched between a high-CTE outermost layer and a high-CTE first wiring board to reduce stress strain inside the second wiring board. Therefore, cracking due to stress concentration, which tends to occur in a second wiring board having a fine wiring layer, can be prevented, and reliability of the wiring board unit can be improved.

Since the results of Evaluation Condition 5 were equivalent to those of other evaluation conditions, it can be said that there is no great difference in crack resistance between the wiring formed using a damascene method and the wiring formed using a SAP method, although these methods are different from each other.

The above embodiments are mere examples, and specific details may be modified as appropriate as a matter of course.

For example, although the reinforcement layers were formed only as outermost layers in the above examples, the effects of the reinforcement layers are not limited to be exerted by being present only as outermost layers. In other words, the reinforcement layers can each be formed adjacent to or close to an outermost layer.

In the above examples, the material of the reinforcement layers was a filler-containing resin; however, the material of the reinforcement layers is not limited to this. Various materials can be used for the reinforcement layers as long as the materials have a CTE of 40 ppm/K or lower.

Although a damascene method or a SAP method is used in the present disclosure, methods are not limited to these, but may be changed to other methods.

The present invention can be applied to various semiconductor devices including a wiring board which is provided with an interposer or the like provided between a main substrate and chips.

The semiconductor elements of the present disclosure can be replaced by other wiring board.

The present disclosure also encompasses the following modes.

### Mode 1

A substrate with a support, the substrate including a support and a wiring board provided on the support, wherein
the wiring board includes an insulating film on the inside thereof configured by a first organic insulating resin;
the wiring board has a first surface and a second surface each provided with electrodes that can be connected to a semiconductor element and the like;
at least one of an upper surface layer and a lower surface layer of the wiring board is provided with an insulating film configured by a second organic insulating resin; and
the second organic insulating resin has a CTE lower than that of the first organic insulating resin.

### Mode 2

The substrate with a support, according to Mode 1, wherein
the second organic insulating resin has a CTE of 40 ppm/K or lower.

### Mode 3

The substrate with a support, according to Mode 1 or 2, wherein
the second organic insulating resin contains a filler.

### Mode 4

The substrate with a support, according to Mode 3, wherein
the filler contains silicon or silicon compounds.

### Mode 5

The substrate with a support, according to any one of Modes 1 to 4, wherein
the support is a glass substrate.

### Mode 6

The substrate with a support, according to any one of Modes 1 to 5, wherein
wiring in the wiring board or vias to connect portions of the wiring are made of copper or an alloy containing copper; and
portions of a surface of the first or second organic insulating resin, with which the wiring or the vias are in contact, are provided with respective portions of a barrier metal layer.

### Mode 7

The substrate with a support, according to Mode 6, wherein
the barrier metal layer contains titanium or tantalum or compounds thereof.

### Mode 8

The substrate with a support, according to any one of Modes 1 to 7, wherein
portions of respective electrodes that can be connected to the semiconductor element and the like penetrate a second organic insulating layer which is an outermost layer.

### Mode 9

The substrate with a support, according to any one of Modes 1 to 8, wherein
a release layer is arranged between the support and the wiring board; and
an intermediate layer is arranged between the wiring board and the release layer.

### Mode 10

The substrate with a support, according to Mode 9, wherein
the intermediate layer is made of nickel, copper, titanium, or an alloy of these, or configured by multiple layers that are made of two or more of these materials.

### Mode 11

The substrate with a support, according to any one of Modes 1 to 10, wherein
a filler-containing organic insulating resin is not provided to regions in the first
surface and the second surface of the wiring board, the regions being regions where electrodes to be connected to the semiconductor element and the like are provided.

### Mode 12

A semiconductor device, wherein
the semiconductor elements or an other wiring board are joined with the first
surface of the substrate with a support according to any one of Modes 1 to 11; and the support is peeled and removed.

### Mode 13

The semiconductor device according to Mode 12, wherein
the semiconductor element and the like are joined with the second surface of the wiring board.

### Mode 14

A method of producing a substrate with a support, according to Mode 11, including
a first step of forming a release layer on a support;
a second step of forming a reinforcement layer on the release layer;
a third step of forming connection holes in the reinforcement layer;
a fourth step of forming a photosensitive resin layer on the reinforcement layer in which the connection holes are formed;
a fifth step of patterning the photosensitive resin layer to form wiring;
a sixth step of repeating the fifth step an arbitrary number of times;
a seventh step of forming a reinforcement layer having openings on the wiring formed at the sixth step; and
a sixth step of embedding an electrically conductive material in respective portions of the connection holes of the reinforcement layer in which the openings have been formed at the eighth step.

### Mode 15

The method of forming a substrate with a support, according to Mode 14, including
a step of removing portions of the reinforcement layer on the release layer and filling a filling material in areas from which portions of the reinforcement layer have been removed, following the second step or the third step.

### Mode 16

A method of producing a semiconductor device, including
a first step of joining semiconductor elements and other others with the first surface of the wiring board in the substrate with a support according to any one of Modes 1 to 11;
a second step of peeling the support from the substrate with a support; and
a third step of joining the wiring board, from which the support has been peeled, with an other wiring board.

### Mode 17

A method of producing a semiconductor device, including
a first step of joining a semiconductor element and the like with the first surface of the wiring board in the substrate with a support according to any one of Modes 1 to 11;
a second step of peeling the support from the substrate with a support;
a third step of joining a semiconductor element and the like with the second surface of the wiring board from which the support has been peeled; and
a fourth step of joining the wiring board, in which the semiconductor element and the like have been joined with the first surface and the second surface, with an other wiring board.

### Mode 18

The method of producing a semiconductor device according to Modes 14 to 17, including
a step of removing portions of the reinforcement layer on the second surface of the
wiring board to provide openings in the reinforcement layer, following the second step.

The present disclosure further encompasses the following modes.

### Mode 19

A wiring board unit including
a first wiring board, and
a second wiring board joined with the first wiring board, in which,
semiconductor elements are mounted on a surface of the second wiring board facing away from a joining surface joined with the first wiring board, wherein
a reinforcement layer is provided as an outermost layer on one side of the second wiring board on which the semiconductor elements are mounted.

### Mode 20

The wiring board unit according to Mode 19, wherein
the reinforcement layer is provided with junction electrodes for connection between the semiconductor elements and the second wiring board.

### Mode 21

The wiring board unit according to Mode 19 or 20, wherein
the second wiring board is a multilayer wiring board.

### Mode 22

The wiring board unit according to any one of Modes 19 to 21, wherein
the reinforcement layer is a filler-containing resin.

### Mode 23

The wiring board unit according to any one of Modes 19 to 22, wherein
the resin configuring the reinforcement layer has a CTE lower than that of a photosensitive resin layer configuring the second wiring board.

### Mode 24

The wiring board unit according to any one of Modes 19 to 23, wherein
the resin configuring the reinforcement layer has a CTE of 40 ppm/K or lower.

### Mode 25

The wiring board unit according to any one of Modes 19 to 24, wherein
the second wiring board includes a wiring section provided with a seed adhesion layer on one surface thereof on which the semiconductor elements are mounted.

### Mode 26

The wiring board unit according to Mode 25, wherein
the seed adhesion layer is a layer containing titanium.

### Mode 27

The wiring board unit according to any one of Modes 19 to 26, wherein
the second wiring board includes an interlayer insulating layer made of a photosensitive insulating resin.

### Mode 28

A substrate with a support, the substrate including a second wiring board, a release layer, and a support, wherein
the release layer is arranged between the support and the second wiring board; and
an intermediate layer is arranged between the second wiring board and the release layer.

### Mode 29

The substrate with a support, according to Mode 28, wherein
the intermediate layer is made of nickel, copper, titanium, or an alloy of these, or
configured by multiple layers that are made of two or more of these materials.

### Mode 30

The wiring board unit or the substrate with a support, according to Modes 19 to 29, wherein
part of the connection holes provided to connect between the second wiring board and the semiconductor elements is formed in a photosensitive resin layer without them passing through the reinforcement layer.

### Mode 31

A method of producing a wiring board unit according to Modes 19 to 29, including
a first step of forming a release layer on a support;
a second step of forming a reinforcement layer on the release layer;
a third step of forming connection holes in the reinforcement layer;
a fourth step of forming a photosensitive resin layer on the reinforcement layer in which the connection holes are formed;
a fifth step of forming openings in the photosensitive resin layer so as to match at least part of the connection holes of the reinforcement layer;
a sixth step of embedding an electrically conductive material in the connection holes;
a seventh step of forming a wiring layer on the photosensitive resin layer to form a second wiring board;
an eighth step of joining the second wiring board with a first wiring board through a surface thereof facing away from the surface on which the release layer is formed; and
a ninth step of peeling the release layer to separate the support from the second wiring board joined with the first wiring board.

### Mode 32

A method of producing a wiring board unit according to Mode 19 or 20, including a first step of forming a release layer on a support;
a second step of forming a reinforcement layer on the release layer;
a third step of forming connection holes in the reinforcement layer;
a fourth step of forming a photosensitive resin layer on the reinforcement layer in which the connection holes are formed;
a fifth step of forming openings in the photosensitive resin layer so as to match at least part of the connection holes of the reinforcement layer;
a sixth step of embedding an electrically conductive material in the connection holes;
a seventh step of forming a wiring layer on the photosensitive resin layer to form a second wiring board;
an eighth step of joining the second wiring board with a first wiring board through a surface thereof facing away from the surface on which the release layer is formed;
a ninth step of peeling the release layer to separate the support from the second wiring board joined with the first wiring board; and
a tenth step of forming connection holes in the reinforcement layer exposed due to separation of the support.

### Mode 33

The method of producing a wiring board unit according to Mode 30 or 31, wherein a lithography technique is used in the step of forming a pattern in the reinforcement layer.

### Mode 34

The method of producing a wiring board unit according to Mode 30 or 31, wherein a laser processing technique is used in the step of forming a pattern in the reinforcement layer.

[Reference Signs List] 1, 51: Support; 2, 53: Release layer; 3: Photosensitive resin layer; 4: Seed adhesion layer; 5: Seed layer; 6: Conductor layer; 7: Resist pattern; 8: Solder resist layer; 9: Surface treatment layer; 10, 58: Solder; 11, 54: Substrate with a support; 12: FC-BGA substrate; 13: Laser light; 14: Wiring board unit; 15: Semiconductor element; 16: Semiconductor device; 18, 68: Reinforcement layer; 19: Fine wiring layer; 20: Underfill layer; 50: Intermediate layer; 52: Wiring board; 55: Semiconductor element and the like; 56: Upper surface of wiring board 52; 57: Lower surface of wiring board 52; 59: Underfill; 60: Molding resin,; 61: Other wiring board; 62: Solder or copper post; 63: Barrier metal layer; 64: Wiring; 67: Inner insulating film; 69: Plating resist; 70: Copper plating; 71: First surface; 72: Second surface.

What is claimed is:

1. A substrate with a support, the substrate including a support and a wiring board provided on the support, wherein
the wiring board includes an insulating film on the inside thereof configured by a first organic insulating resin;
the wiring board has a first surface and a second surface each provided with electrodes that can be connected to a semiconductor element and the like;
at least one of an upper surface layer and a lower surface layer of the wiring board is provided with an insulating film configured by a second organic insulating resin; and
the second organic insulating resin has a CTE lower than that of the first organic insulating resin.

2. The substrate with a support, of claim 1, wherein
the second organic insulating resin has a CTE of 40 ppm/K or lower.

3. The substrate with a support, of claim 1, wherein
the support is a glass substrate.

4. The substrate with a support, of claim 1, wherein
wiring in the wiring board or vias to connect portions of the wiring are made of copper or an alloy containing copper; and
portions of a surface of the first or second organic insulating resin, with which the wiring or the vias are in contact, are provided with respective portions of a barrier metal layer.

5. The substrate with a support, of claim 1, wherein
portions of respective electrodes that can be connected to the semiconductor element and the like penetrate a second organic insulating layer which is an outermost layer.

6. The substrate with a support, of claim 1, wherein
a release layer is arranged between the support and the wiring board; and
an intermediate layer is arranged between the wiring board and the release layer.

7. The substrate with a support, of claim 1, wherein
a filler-containing organic insulating resin is not provided to regions in the first surface and the second surface of the wiring board, the regions being regions where electrodes to be connected to the semiconductor element and the like are provided.

8. A semiconductor device, wherein
the semiconductor elements or another wiring board are joined with the first surface of the substrate with a support of claim 1; and
the support is peeled and removed.

9. The semiconductor device of claim 8, wherein
the semiconductor element and the like are joined with the second surface of the wiring board.

10. A method of producing a substrate with a support, of claim 7, comprising
a first step of forming a release layer on a support;
a second step of forming a reinforcement layer on the release layer;
a third step of forming connection holes in the reinforcement layer;
a fourth step of forming a photosensitive resin layer on the reinforcement layer in which the connection holes are formed;
a fifth step of patterning the photosensitive resin layer to form wiring;
a sixth step of repeating the fifth step an arbitrary number of times;
a seventh step of forming a reinforcement layer having openings on the wiring formed at the sixth step; and
a sixth step of embedding an electrically conductive material in respective portions of the connection holes of the reinforcement layer in which the openings have been formed at the eighth step.

11. A method of producing a semiconductor device, comprising
a first step of joining semiconductor elements and other others with the first surface of the wiring board in the substrate with a support of claim 1;
a second step of peeling the support from the substrate with a support; and
a third step of joining the wiring board, from which the support has been peeled, with an other wiring board.

12. A method of producing a semiconductor device, comprising
a first step of joining a semiconductor element and the like with the first surface of the wiring board in the substrate with a support of claim 1;
a second step of peeling the support from the substrate with a support;
a third step of joining a semiconductor element and the like with the second surface of the wiring board from which the support has been peeled; and
a fourth step of joining the wiring board, in which the semiconductor element and the like have been joined with the first surface and the second surface, with another wiring board.

13. The method of producing a semiconductor device of claim 12, comprising
a step of removing portions of the reinforcement layer on the second surface of the wiring board to provide openings in the reinforcement layer, following the second step.

14. A wiring board unit, comprising:
a first wiring board, and
a second wiring board joined with the first wiring board, in which,
semiconductor elements are mounted on a surface of the second wiring board facing away from a joining surface joined with the first wiring board, wherein
a reinforcement layer is provided as an outermost layer on one side of the second wiring board on which the semiconductor elements are mounted.

15. The wiring board unit of claim 14, wherein the resin configuring the reinforcement layer has a CTE lower than that of a photosensitive resin layer configuring the second wiring board.

16. The wiring board unit of claim 14, wherein the resin configuring the reinforcement layer has a CTE of 40 ppm/K or lower.

17. The wiring board unit of claim 14, wherein
the second wiring board includes a wiring section provided with a seed adhesion layer on one surface thereof on which the semiconductor elements are mounted.

18. The wiring board unit of claim 14, further comprising a substrate including the second wiring board, a release layer, and a support, wherein
the release layer is arranged between the support and the second wiring board; and
an intermediate layer is arranged between the second wiring board and the release layer.

19. A method of producing a wiring board unit of claim 14, comprising
a first step of forming a release layer on a support;
a second step of forming a reinforcement layer on the release layer;
a third step of forming connection holes in the reinforcement layer;
a fourth step of forming a photosensitive resin layer on the reinforcement layer in which the connection holes are formed;
a fifth step of forming openings in the photosensitive resin layer so as to match at least part of the connection holes of the reinforcement layer;
a sixth step of embedding an electrically conductive material in the connection holes;
a seventh step of forming a wiring layer on the photosensitive resin layer to form a second wiring board;
an eighth step of joining the second wiring board with a first wiring board through a surface thereof facing away from the surface on which the release layer is formed; and
a ninth step of peeling the release layer to separate the support from the second wiring board joined with the first wiring board.
